(19) United States
(12) Patent Application Publication
(10) Pub. No.: US 2025/0063726 A1
(43) Pub. Date: Feb. 20, 2025

(54) SEMICONDUCTOR MEMORY DEVICE

(71) Applicant: Samsung Electronics Co., Ltd., Suwon-si (KR)

(72) Inventors: Si Nyeon KIM, Suwon-si (KR); Seong Jae BYEON, Suwon-si (KR)

(21) Appl. No.: 18/738,410

(22) Filed: Jun. 10, 2024

(30) Foreign Application Priority Data
Aug. 14, 2023 (KR) 10-2023-0106307

(51) Int. Cl. H10B 12/00

(52) U.S. Cl. CPC H10B 12/482; H10B 12/315; H10B 12/488

(57) ABSTRACT

A semiconductor memory device is provided. The semiconductor memory device includes a first bit line extending in a first direction on a substrate, a word line on the first bit line, and extending in a second direction intersecting the first direction, a first channel pattern between the first bit line and the word line, and extending along a first side wall of the word line and a first contact pattern on the first channel pattern, wherein in a cross-sectional view taken along the first channel pattern in the second direction, the first contact pattern includes a connecting part on the first channel pattern, and a protruding part which is connected to the connecting part, and extends along a side wall of the first channel pattern.

### CROSS-REFERENCE TO RELATED APPLICATION

This application claims priority under 35 U.S.C. 119 to Korean Patent Application No. 10-2023-0106307 filed on Aug. 14, 2023, in the Korean Intellectual Property Office, the contents of which in its entirety are herein incorporated by reference.

### BACKGROUND

### 1. Field of the Disclosure

The present disclosure relates to a semiconductor memory device, and more particularly, to semiconductor memory devices including a vertical channel transistor (VCT).

### 2. Description of the Related Art

It may be desirable to increase the degree of integration of a semiconductor memory device to provide excellent performance and low price sought by consumers. In the case of semiconductor memory devices, because the degree of integration is an important factor in determining the price of a product, an increased degree of integration may be particularly desirable.

In the case of a two-dimensional or planar semiconductor memory device, the degree of integration is primarily determined by an area occupied by unit memory cells, and is therefore greatly affected by the level of a fine pattern formation technique. However, because ultra-expensive equipment may be required to miniaturize the pattern, the degree of integration of a two-dimensional semiconductor memory device is increasing, but is still limited. Accordingly, semiconductor memory devices including vertical channel transistors whose channels extend in a vertical direction have been proposed as one approach to increasing the degree of integration.

### SUMMARY

Aspects of the present disclosure provide a semiconductor memory device having improved integration and electrical characteristics.

According to an aspect of the present disclosure, there is provided a semiconductor memory device comprising a first bit line extending in a first direction on a substrate, a word line on the first bit line, and extending in a second direction intersecting the first direction, a first channel pattern between the first bit line and the word line, and extending along a first side wall of the word line; and a first contact pattern on the first channel pattern, wherein in a cross-sectional view taken along the first channel pattern in the second direction, the first contact pattern includes a connecting part on the first channel pattern, and a protruding part which is connected to the connecting part, and extends along a side wall of the first channel pattern.

According to an aspect of the present disclosure, there is provided a semiconductor device comprising a first bit line extending in a first direction, on a substrate, a word line on the first bit line, and extending in a second direction intersecting the first direction, a first channel pattern between the first bit line and the word line, and extending in a third direction intersecting the first direction and the second direction along a first side wall of the word line, a first contact pattern on the first channel pattern, a second bit line which is spaced apart from the first bit line in the second direction, and extends in the first direction, a second channel pattern between the second bit line and the word line, spaced apart from the first channel pattern in the second direction, and extending in the third direction along the first side wall of the word line, a second contact pattern on the second channel pattern and an insulating pattern between the first channel pattern and the second channel pattern, wherein the insulating pattern includes a first portion between the first contact pattern and the second contact pattern, and a second portion below the first portion relative to the substrate providing a base reference plane, and between the first channel pattern and the second channel pattern, and wherein a width of the first portion is less than a width of the second portion.

According to an aspect of the present disclosure, there is provided a semiconductor device comprising a first bit line extending in a first direction, on a substrate, a word line on the first bit line, and extending in a second direction intersecting the first direction, a first channel pattern between the first bit line and the word line, and extending along a first side wall of the word line in a third direction intersecting the first direction and the second direction, a gate insulating film between the first channel pattern and the word line, and extending in the third direction along a side wall of the first channel pattern and the first side wall of the word line, a first contact pattern on the first channel pattern, an insulating pattern extending along a side face of the first contact pattern and a side face of the first channel pattern, a landing pad on the first contact pattern and a capacitor on the landing pad and connected to the first channel pattern, wherein in a cross-sectional view taken along the first channel pattern in the second direction, the first contact pattern includes a connecting part on the first channel pattern, and a protruding part connected to the connecting part and extending along the side wall of the first channel pattern, and wherein a lower surface of the protruding part is located above a lower surface of the first channel pattern relative to the substrate providing a base reference plane.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

### BRIEF DESCRIPTION OF DRAWINGS

The above and other aspects and features of the present disclosure will become more apparent by describing in detail illustrative embodiments thereof with reference to the attached drawings, in which:

FIG. 1 is a layout diagram that illustrates a semiconductor memory device according to some embodiments.

FIG. 2 is a cross-sectional view taken along lines A-A, B-B, and C-C of FIG. 1.

FIG. 3 is a cross-sectional view taken along lines D-D, E-E, and F-F of FIG. 1.

FIG. 4 is an enlarged view showing a portion P of FIG. 2.

FIG. 5 is an enlarged view showing a portion Q of FIG. 2.

FIG. 6 is an enlarged view showing a portion R of FIG. 3.

FIG. 7 is a layout diagram that illustrates a semiconductor memory device according to some other embodiments.

FIG. 8 is a cross-sectional view taken along lines A-A, B-B, and C-C of FIG. 7.

FIG. 9 is a cross-sectional view taken along lines D-D, E-E, and F-F of FIG. 7.

FIG. 10 is an enlarged view showing a portion R of FIG. 9.

FIGS. 11 to 14 are diagrams that illustrate a semiconductor memory device according to some other embodiments.

FIGS. 15 to 17 are diagrams that illustrate a semiconductor memory device according to some other embodiments.

FIGS. 18 and 19 are diagrams that illustrate semiconductor memory device according to some other embodiments.

FIGS. 20 to 24 are diagrams that illustrate a semiconductor memory device according to some other embodiments.

FIGS. 25 to 28 are diagrams that illustrate a semiconductor memory device according to some other embodiments, respectively.

FIGS. 29 to 51 are diagrams of intermediate structures that illustrate a method for fabricating the semiconductor memory device according to some embodiments.

### DETAILED DESCRIPTION OF THE EMBODIMENTS

Embodiments according to the inventive concept of the present disclosure will be described below with reference to the accompanying drawings. Like reference numerals in the drawings denote like elements, and thus their description will be omitted. As used herein, the term “and/or” includes any and all combinations of one or more of the associated listed items. It is noted that aspects described with respect to one embodiment may be incorporated in different embodiments although not specifically described relative thereto. That is, all embodiments and/or features of any embodiments can be combined in any way and/or combination.

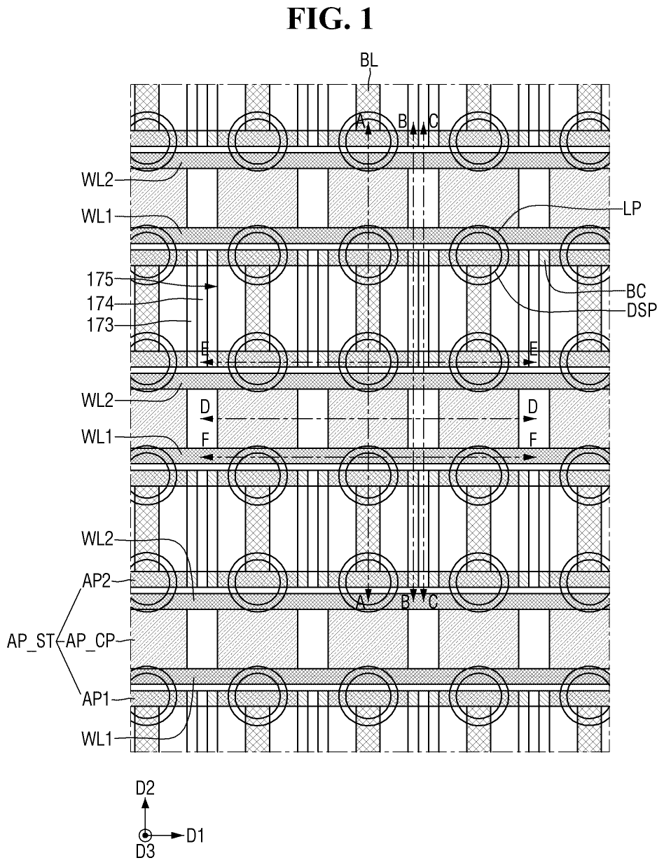

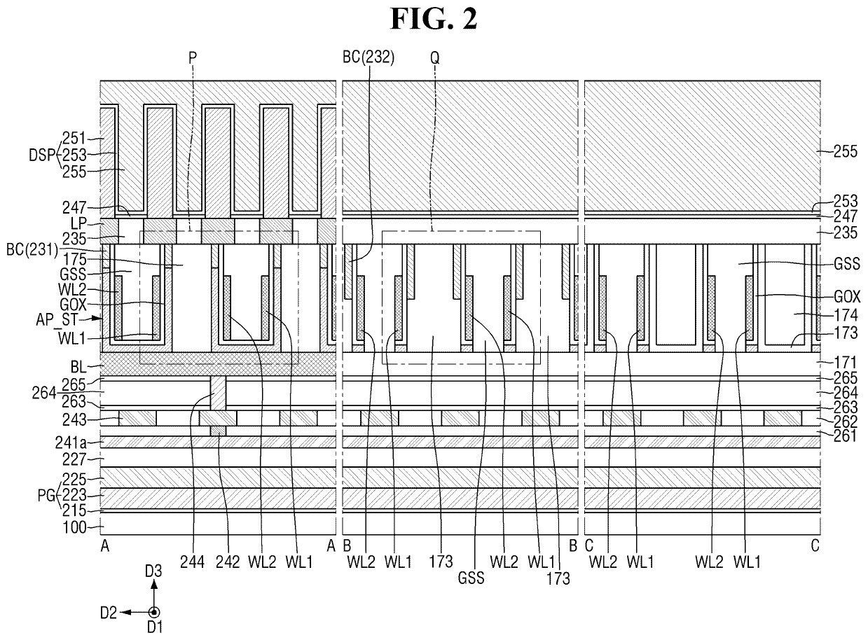

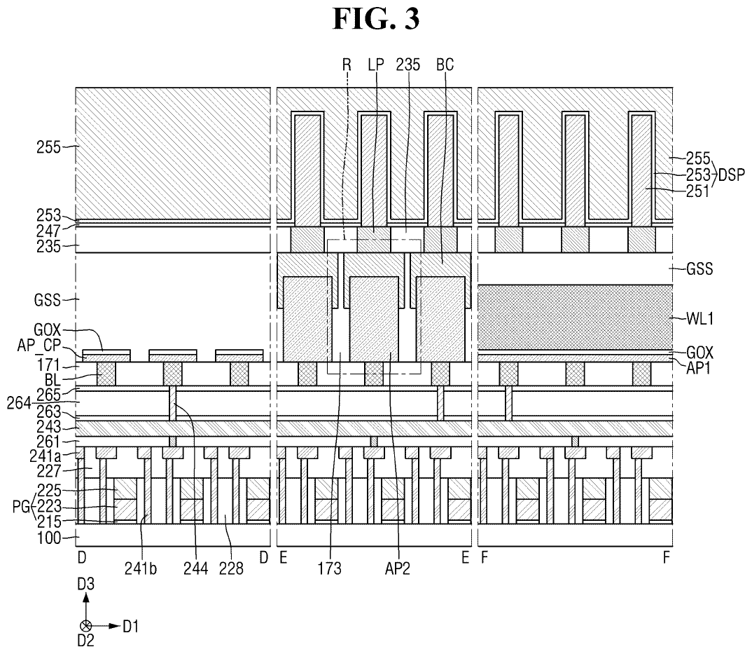

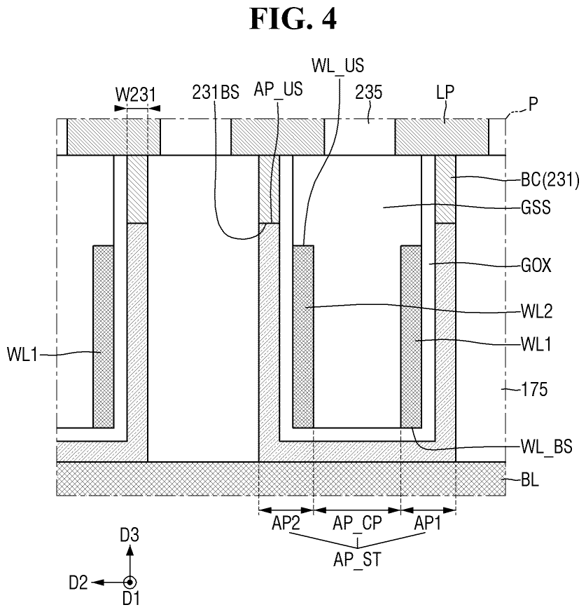

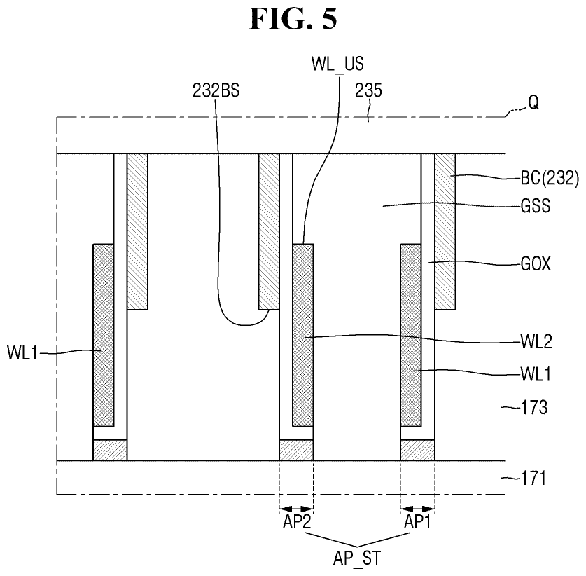

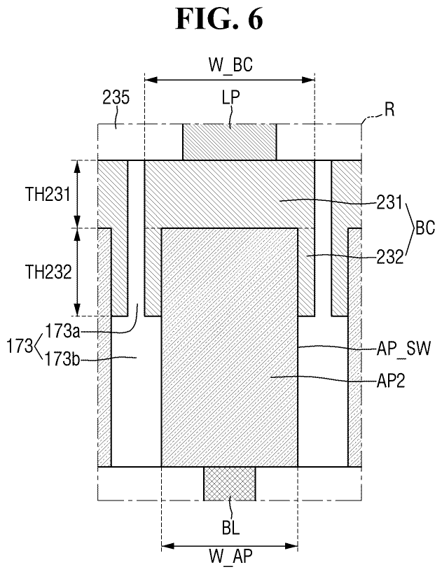

FIG. 1 is a layout diagram that illustrates a semiconductor memory device according to some embodiments. FIG. 2 is a cross-sectional view taken along lines A-A, B-B, and C-C of FIG. 1. FIG. 3 is a cross-sectional view taken along lines D-D, E-E, and F-F of FIG. 1. FIG. 4 is an enlarged view showing a portion P of FIG. 2. FIG. 5 is an enlarged view showing a portion Q of FIG. 2. FIG. 6 is an enlarged view showing a portion R of FIG. 3.

The semiconductor memory device according to the embodiments of the present disclosure may include memory cells including a vertical channel transistor (VCT).

Referring to FIGS. 1 to 6, the semiconductor memory device according to some embodiments may include a peri-gate structure PG, bit lines BL, word lines WL1 and WL2, channel structures AP_ST, a protruding insulating pattern 175, a contact pattern BC, an insulating liner film 173, an insulating filling film 174, and data storage patterns DSP.

The substrate 100 may be a silicon substrate, or may include other materials, for example, but not limited to, silicon germanium, indium antimonide, lead telluride, indium arsenide, indium phosphide, gallium arsenide, and/or gallium antimonide.

The peri-gate structure PG may be disposed on the substrate 100. The substrate 100 may include a cell array region and a peripheral circuit region. The peri-gate structure PG may be disposed over the cell array region and the peripheral circuit region. In other words, a part of the peri-gate structure PG may be disposed in the cell array region of the substrate 100, and the rest of the peri-gate structure PG may be disposed in the peripheral circuit region of the substrate 100.

The peri-gate structure PG may be included in a sensing transistor, a transfer transistor, a drive transistor, etc. The types of transistors disposed in the cell array region and the peripheral circuit region may vary depending on the design and layout of the semiconductor memory device.

The peri-gate structure PG may include a peri-gate insulating film 215, a peri-lower conductive pattern 223, and a peri-upper conductive pattern 225.

The peri-gate insulating film 215 may include a silicon oxide film, a silicon oxynitride film, a high dielectric constant insulating film having a higher dielectric constant than a silicon oxide film, or a combination thereof. The high dielectric constant insulating film may include, for example, but not limited to, one or more of a metal oxide, a metal oxynitride, a metal silicon oxide, and/or a metal silicon oxynitride.

The peri-lower conductive pattern 223 and the peri-upper conductive pattern 225 may each include a conductive material. For example, the peri-lower conductive pattern 223 and the peri-upper conductive pattern 225 may each include one or more of a doped semiconductor material, a conductive metal nitride, a conductive metal silicon nitride, a metal carbonitride, a conductive metal silicide, a conductive metal oxide, a two-dimensional (2D) material, a metal, and/or a metal alloy. Although the peri-gate structure PG is shown to include a plurality of conductive patterns, the embodiments of the disclosure are not limited thereto.

In the semiconductor device according to some embodiments, the two-dimensional material may be a metallic material and/or a semiconductor material. The 2D material may include a 2D allotrope or a 2D compound, and may include, but is not limited to, one or more of graphene, molybdenum disulfide (MoS₂), molybdenum diselenide (MoSe₂), tungsten diselenide (WSe₂), and/or tungsten disulfide (WS₂). That is, because the above-mentioned 2D materials are only listed as an example, the 2D materials that may be included in the semiconductor memory device of the present disclosure are not limited by the above-mentioned materials.

The first peri-lower insulating film 227 and the second peri-lower insulating film 228 are disposed on the substrate 100. The first peri-lower insulating film 227 and the second peri-lower insulating film 228 may each be made of an insulating material.

A first peri-wiring line 241a and a peri-contact plug 241b may be disposed inside the first peri-lower insulating film 227 and the second peri-lower insulating film 228. Although the first peri-wiring line 241a and the peri-contact plug 241b are shown to be different films from each other, embodiments of the present disclosure are not limited thereto. A boundary between the first peri-wiring line 241a and the peri-contact plug 241b may not be distinguished. The first peri-wiring line 241a and the peri-contact plug 241b each include a conductive material.

The first peri-upper insulating film 261 and the second peri-upper insulating film 262 may be disposed on the first peri-wiring line 241a and the peri-contact plug 241b. The first peri-upper insulating film 261 and the second peri-upper insulating film 262 may each be made of an insulating material.

A second peri-wiring line 243 and a peri-via plug 242 are disposed on the first peri-wiring line 241a. The peri-via plug 242 may be disposed inside the first peri-upper insulating film 261. The second peri-wiring line 243 may be disposed inside the second peri-upper insulating film 262.

The second peri-wiring line 243 and the peri-via plug 242 may be connected to the first peri-wiring line 241a. The peri-via plug 242 may connect the first peri-wiring line 241a and the second peri-wiring line 243. The second peri-wiring line 243 and the peri-via plug 242 each include a conductive material. Although the second peri-wiring line 243 and the peri-via plug 242 are shown as being different films from each other, the embodiments of the disclosure are not limited thereto. A boundary between the second peri-wiring line 243 and the peri-via plug 242 may not be distinguished.

A third peri-upper insulating film 263, a fourth peri-upper insulating film 264, and a fifth peri-upper insulating film 265 may be sequentially disposed on the second peri-wiring line 243. The third peri-upper insulating film 263, the fourth peri-upper insulating film 264, and the fifth peri-upper insulating film 265 may each be made of an insulating material.

The fourth peri-upper insulating film 264 may be made of an insulating material different from that of the third peri-upper insulating film 263 and the fifth peri-upper insulating film 265. For example, although the fourth peri-upper insulating film 264 may be made of an oxide-based insulating material, and the third peri-upper insulating film 263 and the fifth peri-upper insulating film 265 may be made of a nitride-based insulating material, the embodiments of the disclosure are not limited thereto.

A cell connection plug 244 may be disposed inside the third peri-upper insulating film 263, the fourth peri-upper insulating film 264, and the fifth peri-upper insulating film 265. The cell connection plug 244 may be connected to the second peri-wiring line 243. The cell connection plug 244 includes a conductive material. A peri-upper insulating film may be made up of a single film may be disposed in the cell connection plug 244, unlike the shown example.

The bit lines BL are disposed on the peri-gate structure PG. Specifically, the bit lines BL may be disposed on the fifth peri-upper insulating film 265. For example, the bit lines BL may make contact with the fifth peri-upper insulating film 265.

The bit line BL may extend lengthwise in a second direction D2. Adjacent bit lines BL may be spaced apart in a first direction D1. The bit line BL includes a long side wall extending in the second direction D2, and a short side wall extending in the first direction D1.

Although not shown, each bit line BL may extend from the cell array region to the peripheral circuit region. Ends of each bit line BL may be disposed on the peripheral circuit region of the substrate 100.

Each bit line BL may be disposed on the cell connection plug 244. Each bit line BL may be connected to the cell connection plug 244. Each bit line BL may include, for example, one or more of a semiconductor material, a conductive metal nitride, a conductive metal silicon nitride, a metal carbonitride, a conductive metal silicide, a conductive metal oxide, a two-dimensional material, a metal, and/or a metal alloy. Although each bit line BL is shown as being a single film, the embodiments of the disclosure are not limited thereto.

The cell lower insulating film 171 may be disposed on the fifth peri-upper insulating film 265. The cell lower insulating film 171 is disposed between the bit lines BL spaced apart in the first direction D1. The cell lower insulating film 171 may be made of an insulating material.

The protruding insulating pattern 175 may be disposed on the bit line BL and the cell lower insulating film 171. The protruding insulating pattern 175 may be made of an insulating material. Although a lower surface of the protruding insulating pattern 175 is shown to be in direct contact with the bit line BL and the cell lower insulating film 171, the embodiments of the disclosure are not limited thereto. For example, an etching stop film may be disposed between the protruding insulating pattern 175 and the cell lower insulating film 171. Further, the etching stop film may be disposed between the protruding insulating pattern 175 and the bit line BL. The etching stop film may include a material having an etch selectivity with respect to the protruding insulating pattern 175.

A channel structure AP_ST may be disposed on each bit line BL. A plurality of channel structures AP_ST may be connected to one bit line BL. The plurality of channel structures AP_ST disposed on one bit line BL may be spaced apart in the second direction D2. For example, the channel structure AP_ST may be disposed two-dimensionally along the first direction D1 and the second direction D2 that intersect each other.

In a cross section taken in the second direction D2, the channel structure AP_ST may have a “U” shape. Specifically, the channel structure AP_ST may include a horizontal part and a vertical part.

The horizontal part of the channel structure AP_ST may extend along the upper surfaces of the bit line BL and the cell lower insulating film 171. The horizontal part of the channel structure AP_ST may be disposed below the word lines WL1 and WL2. The horizontal part of the channel structure AP_ST may overlap a lower surface WL_BS of the word lines WL1 and WL2 in a third direction D3. The horizontal part of the channel structure AP_ST may be disposed below a gate insulating film GOX as shown in FIG. 4.

The vertical part of the channel structure AP_ST may protrude from the horizontal part. The vertical part of the channel structure AP_ST may extend from the horizontal part in the third direction D3. The vertical part of the channel structure AP_ST may extend along a side face of the protruding insulating pattern 175. Specifically, in the cross section taken in the second direction D2, the vertical part of the channel structure AP_ST may extend along the side wall of the protruding insulating pattern 175. The vertical part of the channel structure AP_ST may extend along the side face of the insulating liner film 173. Specifically, in the cross section taken in the first direction D1, the vertical part of the channel structure AP_ST may extend along the side face of the insulating liner film 173.

The vertical part of the channel structure AP_ST may include a first vertical part and a second vertical part. The first vertical part and the second vertical part of the channel structure AP_ST may be spaced apart in parallel to the second direction D2.

The channel structure AP_ST may include an oxide semiconductor material. The channel structure AP_ST may include, for example, a metal oxide. As an example, the channel structure AP_ST may be an amorphous metal oxide film. As another example, the channel structure AP_ST may be a polycrystalline metal oxide film. As yet another example, the channel structure AP_ST may be a combined state of the amorphous metal oxide film and the polycrystalline metal oxide film. As still another example, the channel structure AP_ST may be a CAAC (c-axis aligned crystalline) metal oxide film.

The channel structure AP_ST may include, for example, but not limited to, one or more of indium oxide, tin oxide, zinc oxide, In—Zn-based oxide (IZO), Sn—Zn-based oxide, Al—Zn-based oxide, Zn—Mg-based oxide, Sn—Mg-based oxide, In—Mg-based oxide, In—Ga-based oxide (IGO), In—Ga—Zn-based oxide (IGZO), In—Al—Zn-based oxide, In—Sn—Zn-based oxide, Sn—Ga—Zn-based oxide, Al—Ga—Zn-based oxide, Sn-Al—Zn-based oxide, In—Hf—Zn-based oxide, In—La—Zn-based oxide, In—Ce—Zn-based oxide, In-Pr—Zn-based oxide, In-Nd—Zn-based oxide, In—Sm—Zn-based oxide, In—Eu—Zn-based oxide, In—Gd—Zn-based oxide, In—Tb—Zn-based oxide, In—Dy—Zn-based oxide, In—Ho—Zn-based oxide, In—Er—Zn-based oxide, In—Tm—Zn-based oxide, In—Yb—Zn-based oxide, In—Lu—Zn-based oxide, In—Sn—Ga—Zn-based oxide, In—Hf—Ga—Zn-based oxide, In—Al—Ga—Zn-based oxide, In—Sn—Al—Zn-based oxide, In—Sn—Hf-Zn-based oxide, and/or In—Hf—Al—Zn-based oxide.

Here, the In—Ga—Zn-based oxide means an oxide having In, Ga, and Zn as main components, but does not mean a ratio of In, Ga, and Zn. That is, taking IGZO (indium gallium zinc oxide) as an example, the channel structure AP_ST may include IGZO (indium gallium zinc oxide, InₓGa_{y}Zn_{z}O). IGZO (In:Ga:Zn=1:1:1) containing indium, gallium and zinc at the same ratio may be an In—Ga—Zn-based oxide. A Ga-rich IGZO may have a higher ratio of gallium than IGZO (In:Ga:Zn=1:1:1), and a lower ratio of indium than IGZO (In:Ga:Zn=1:1:1). The Ga-rich IGZO may also be an In—Ga—Zn-based oxide. An In-rich IGZO may also have a higher ratio of indium than IGZO (In:Ga:Zn=1:1:1) and a lower ratio of gallium than IGZO (In:Ga:Zn=1:1:1). An In-rich IGZO may also be an In—Ga—Zn-based oxide.

Although the above description has been made using the IGZO material, the embodiments of the disclosure are not limited thereto. The above description may be applied when the channel structures AP_ST each include a ternary or more metal oxide. Also, when the channel structure AP_ST includes the In—Ga—Zn-based oxide, the channel structure AP_ST may further include a doped metal element other than In, Ga, and Zn.

The channel structure AP_ST may include a first channel pattern AP1, a second channel pattern AP2, and a connecting channel pattern AP_CP. The connecting channel pattern AP_CP may connect the first channel pattern AP1 and the second channel pattern AP2. The first channel pattern AP1 and the second channel pattern AP2 may be spaced apart in the second direction D2.

The first channel pattern AP1, the second channel pattern AP2, and the connecting channel pattern AP_CP may be disposed on the bit line BL. The first channel pattern AP1 and the second channel pattern AP2 may be connected to the bit line BL.

The first channel pattern AP1 may include a part of the horizontal part of the channel structure AP_ST, and the first vertical part of the channel structure AP_ST. A part of the horizontal part of the channel structure AP_ST may be a horizontal part of the first channel pattern AP1. The first vertical part of the channel structure AP_ST may be a vertical part of the first channel pattern AP1.

The second channel pattern AP2 may include another part of the horizontal part of the channel structure AP_ST, and the second vertical part of the channel structure AP_ST. Another part of the horizontal part of the channel structure AP_ST may be the horizontal part of the second channel pattern AP2. The second vertical part of the channel structure AP_ST may be the vertical part of the second channel pattern AP2.

The connecting channel pattern AP_CP includes the rest of the horizontal part of the channel structure AP_ST. The connecting channel patterns AP_CP may be spaced apart in the first direction D1. The connecting channel pattern AP_CP may be spaced apart between a first word line WL1 and a second word line WL2.

The first channel pattern AP1, the second channel pattern AP2, and the connecting channel pattern AP_CP may be distinguished on the basis of the first word line WL1 and the second word line WL2, which will be described below.

The first word line WL1 may include an inner wall that faces the side wall of the protruding insulating pattern 175, and an outer wall opposite to the inner wall in the second direction D2. The outer wall of the first word line WL1 may face a gate separation pattern GSS. A boundary or interface between the first channel pattern AP1 and the connecting channel pattern AP_CP may be an extension line of the outer wall of the first word line WL1 extending in the third direction D3.

The first word line WL1 may include a first side wall and a second side wall. A first side wall of the first word line WL1 may face the side wall of the protruding insulating pattern 175. The first side wall of the first word line WL1 may face the second word line WL2 with the protruding insulating pattern 175 interposed therebetween. The first side wall of the first word line WL1 may be an inner wall. The first side wall of the first word line WL1 may extend along the gate insulating film GOX. The second side wall of the first word line WL1 may face the gate separation pattern GSS. The second side wall of the first word line WL1 may extend along the gate separation pattern GSS. The second side wall of the first word line WL1 may be an outer wall.

The first channel pattern AP1 may be disposed on the first side wall of the first word line WL1. The first channel pattern AP1 may extend along the first side wall of the first word line WL1. The first channel pattern AP1 may be disposed on the inner wall of the first word line WL1.

The second word line WL2 may include a third side wall and a fourth side wall. The third side wall of the second word line WL2 may face a side wall of the protruding insulating pattern 175. The third side wall of the second word line WL2 may face the first word line WL1 with the protruding insulating pattern 175 interposed therebetween. The third side wall of the second word line WL2 may be an inner wall. The third side wall of the second word line WL2 may extend along the gate insulating film GOX. The fourth side wall of the second word line WL2 may face the gate separation pattern GSS. The fourth side wall of the fourth word line WL2 may extend along the gate separation pattern GSS. The fourth side wall of the fourth word line WL2 may be an outer wall.

The second channel pattern AP2 may be disposed on the third side wall of the second word line WL2. The second channel pattern AP2 may extend along the third side wall of the second word line WL2. The second channel pattern AP2 may be disposed on the inner wall of the second word line WL2.

The first word line WL1 and the second word line WL2 may be disposed on the channel structure AP_ST.

Each of the first word line WL1 and the second word line WL2 may extend in the first direction D1. The first word line WL1 and the second word line WL2 may be alternately arranged in the second direction D2. The first word line WL1 may be spaced apart from the second word line WL2 in the second direction D2.

The first word line WL1 and the second word line WL2 may be spaced apart from the bit line BL in the third direction D3. The first word line WL1 and the second word line WL2 may intersect the bit line BL.

The first word line WL1 and the second word line WL2 may be disposed on the horizontal part of the channel structure AP_ST. The first word line WL1 and the second word line WL2 are disposed between the first vertical part of the channel structure AP_ST and the second vertical part of the channel structure AP_ST.

The first word line WL1 is disposed on the first channel pattern AP1. The second word line WL2 is disposed on the second channel pattern AP2. The first word line WL1 and the second word line WL2 are disposed between the first channel pattern AP1 and the second channel pattern AP2. The first channel pattern AP1 is closer to the first word line WL1 than the second word line WL2. The second channel pattern AP2 is closer to the second word line WL2 than the first word line WL1.

An upper surface WL_US of the first word line and an upper surface WL_US of the second word line may be disposed below the upper surface AP_US of the channel structure as shown in FIG. 4. However, the embodiments are not limited thereto. For example, the upper surface WL_US of the first word line and the upper surface WL_US of the second word line may be disposed above the upper surface AP_US of the channel structure AP_ST in other embodiments.

The lower surface WL_BS of the first word line and the lower surface WL_BS of the second word line may completely overlap the channel structure AP_ST in the third direction D3. For example, the lower surface WL_BS of the first word line may completely overlap the first channel pattern AP1 in the third direction D3. Referring to an E-E cross section of FIG. 3, the first channel pattern AP1 may extend in the first direction D1 under the first word line WL1. The lower surface WL_BS of the second word line WL2 may completely overlap the second channel pattern AP2 in the third direction D3.

The lower surfaces WL_BS of the first word line WL1 and the second word line WL2 may overlap the gate insulating film GOX and the channel structure AP_ST. The lower surfaces WL_BS of the first word line WL1 and the second word line WL2 may be disposed on the gate insulating film GOX and the channel structure AP_ST.

The first and second word lines WL1 and WL2 include a conductive material, and may include, for example, one or more of doped polysilicon, conductive metal nitride, conductive metal silicon nitride, metal carbonitride, conductive metal silicide, conductive metal oxide, two-dimensional material, metal, and/or metal alloy.

The first and second word lines WL1 and WL2 may include an upper surface WL_US and a lower surface WL_BS that are opposite to each other in the third direction D3. The lower surfaces of the first and second word lines WL1 and WL2 face the bit line BL.

The gate insulating film GOX may be disposed between the first word line WL1 and the channel structure AP_ST, and between the second word line WL2 and the channel structure AP_ST. The gate insulating film GOX may be disposed between the first word line WL1 and the first active pattern AP1, and between the second word line WL2 and the second active patterns AP2. The gate insulating film GOX may extend in the first direction D1 along with the first word line WL1 and the second word line WL2.

The gate insulating film GOX may extend along the profile of the channel structure AP_ST. The gate insulating film GOX may extend along the horizontal part of the channel structure AP_ST extending along the upper surface of the bit line BL. The gate insulating film GOX may extend in the third direction D3 along the vertical part of the channel structure AP_ST extending along the side face of the protruding insulating pattern 175. The gate insulating film GOX may extend along the first vertical part of the channel structure AP_ST. The gate insulating film GOX may extend along the second vertical part of the channel structure AP_ST.

On the connecting channel pattern AP_CP of the channel structure AP_ST, the gate insulating film GOX may extend along the upper surface of the connecting channel pattern AP_CP. For example, referring to FIGS. 2 and 4, the gate insulating film GOX may be disposed on the upper surface of the connecting channel pattern AP_CP.

In a region in which the connecting channel pattern AP_CP is not disposed, the gate insulating film GOX may overlap the first channel pattern AP1 and the second channel pattern AP2 in the third direction D3. For example, referring to FIGS. 2 and 5, the gate insulating film GOX may be disposed on the first channel pattern AP1 and the second channel pattern AP2. The gate insulating film GOX may completely overlap the first channel pattern AP1 and the second channel pattern AP2 in the third direction D3. The gate insulating film GOX extends only along the lower surfaces and inner walls of the first word line WL1 and the second word line WL2. The gate insulating film GOX may be spaced apart by the gate separation pattern GSS. One side face of the gate insulating film GOX may be coplanar with the outer wall of the first word line WL1 and the side face of the first channel pattern AP1. One side face of the gate insulating film GOX may be coplanar with the outer wall of the second word line WL2 and the side face of the second channel pattern AP2.

The gate insulating film GOX may extend along the side face of the contact pattern BC. The gate insulating film GOX may extend along a side face of a connecting part 231 of the contact pattern BC. The gate insulating film GOX may extend along the side face of the protruding part 232 of the contact pattern BC.

The gate insulating film GOX may extend along the contact pattern BC facing the gate separation pattern GSS. For example, referring to FIG. 4, the gate insulating film GOX extending between the first active pattern AP1 and the first word line WL1 may extend along the side face of the connecting part 231 of the contact pattern BC disposed on the first active pattern AP1. The gate insulating film GOX extending between the second active pattern AP2 and the second word line WL2 may extend along the side face of the connecting part 231 disposed on the second active pattern AP2.

Also, referring to FIG. 5, the gate insulating film GOX may extend along the side face of the protruding part 232. The gate insulating film GOX extending between the first word line WL1 and the insulating liner film 173 may extend along the side face of the protruding part 232 adjacent to the first word line WL1. The gate insulating film GOX extending between the second word line WL2 and the insulating liner film 173 may extend along the side face of the protruding part 232 adjacent to the second word line WL2.

The gate insulating film GOX may include a silicon oxide film, a silicon oxynitride film, a high dielectric constant insulating film having a higher dielectric constant than the silicon oxide film, or a combination thereof.

A part of the gate insulating film GOX may protrude beyond the upper surfaces WL_US of the first and second word lines WL1 and WL2 in the third direction D3. A part of the gate insulating film GOX may protrude beyond the uppermost part of the vertical part of the channel structure AP_ST in the third direction D3. The upper surface of the gate insulating film GOX may be coplanar with the upper surface of the gate separation pattern GSS. The upper surface of the gate insulating film GOX may be coplanar with the upper surface of the protruding insulating pattern 175. The upper surface of the gate insulating film GOX may be coplanar with the upper surface of the insulating liner film 173 and the upper surface of the insulating filling film 174.

The gate separation pattern GSS may be disposed on the bit line BL. The gate separation pattern GSS may be disposed on the channel structure AP_ST, the gate insulating film GOX, the first word line WL1, and the second word line WL2.

In the semiconductor memory device according to some embodiments, the gate separation pattern GSS may make contact with the channel structure AP_ST. The gate separation pattern GSS may be disposed on the connecting channel pattern AP_CP. The gate separation pattern GSS may be spaced apart from the bit line BL in the third direction D3.

The gate separation pattern GSS may be disposed between the first word line WL1 and the second word line WL2 adjacent to each other in the second direction D2. The first word line WL1 and the second word line WL2 may be separated by the gate separation pattern GSS. The gate separation pattern GSS may extend in the first direction D1 between the first word line WL1 and the second word line WL2.

The gate separation pattern GSS may be disposed between the connecting channel patterns AP_CP adjacent in the first direction D1. A lower surface of the gate separation pattern GSS between the connecting channel patterns AP_CP adjacent in the first direction D1 may make contact with the cell lower insulating film 171. The lower surface of the gate separation pattern GSS between the connecting channel patterns AP_CP adjacent in the first direction D1 may be coplanar with the lower surface of the channel structure AP_ST.

In the region in which the connecting channel pattern AP_CP is not disposed, the gate separation pattern GSS may be on and at least partially cover the side face of the gate insulating film GOX, which is coplanar with the side face of the first word line WL1, and the side face of the first channel pattern AP1. In the region in which the connecting channel pattern AP_CP is not disposed, the gate separation pattern GSS may be on and at least partially cover the side face of the gate insulating film GOX, which is coplanar with the side face of the second word line WL2, and the side face of the second channel pattern AP2.

The first word line WL1 may be disposed between the gate separation pattern GSS and the channel structure AP_ST. The second word line WL2 may be disposed between the gate separation pattern GSS and the channel structure AP_ST. The first word line WL1 may be disposed between the gate separation pattern GSS and the first channel pattern AP1. The second word line WL2 may be disposed between the gate separation pattern GSS and the second channel pattern AP2.

The gate separation pattern GSS may be a single film. The gate separation pattern GSS may include a horizontal part and a vertical part. The vertical part of the gate separation pattern GSS may protrude from the horizontal part of the gate separation pattern GSS toward the bit line BL in the third direction D3. The vertical part of the gate separation pattern GSS may be closer to the bit line BL than the horizontal part of the gate separation pattern GSS. The horizontal part of the gate separation pattern GSS may be disposed on the upper surfaces WL_US of the first and second word lines WL1 and WL2. From viewpoint of a cross-sectional view, the gate separation pattern GSS may have a “T” shape.

The upper surface of the gate separation pattern GSS may be disposed at the same height as the upper surface of the protruding insulating pattern 175 on the basis of the upper surface of the bit line BL, i.e., where the upper surface of the bit line BL provides a base reference plane, but the embodiments are not limited thereto.

A height from the upper surface of the bit line BL to the upper surface of the gate separation pattern GSS may be greater than a height from the upper surface of the bit line BL to the uppermost part of the channel structure AP_ST. The uppermost part of the channel structure AP_ST may refer to the upper surface AP_US of the first channel pattern AP1 or the second channel pattern AP2. The height from the upper surface of the bit line BL to the upper surface of the gate separation pattern GSS may be greater than the height from the upper surface of the bit line BL to the upper surface WL_US of the word lines WL1 and WL2.

The height from the upper surface of the bit line BL to the upper surface of the gate separation pattern GSS is shown as being the same as the height from the upper surface of the bit line BL to the uppermost part of the gate insulating film GOX, but the embodiments are not limited thereto.

Landing pads LP may be disposed on the channel structure AP_ST. The landing pads LP may be connected to the first vertical part AP_STV1 of the channel structure and the second vertical part AP_STV2 of the channel structure.

The landing pads LP may be disposed on the first channel pattern AP1 and the second channel pattern AP2. The landing pads LP are connected to the first channel pattern AP1 and the second channel pattern AP2.

From a plan view perspective as shown in FIG. 1, the landing pads LP may have various shapes such as a circular shape, an oval shape, a rectangular shape, a square shape, a rhombic shape, and a hexagonal shape.

The landing pad LP may be disposed on the protruding insulating pattern 175 and the gate separation pattern GSS. The landing pad LP may make contact with the upper surface of the protruding insulating pattern 175 and the upper surface of the gate separation pattern GSS. The landing pad LP may be disposed between the pad separation insulating patterns 235.

The pad separation insulating patterns 235 may be disposed between the landing pads LP. From a plan view as shown in FIG. 1, the landing pads LP may be arranged in the form of a matrix along the first direction D1 and the second direction D2. The upper surface of the landing pad LP may be coplanar with the upper surface of the pad separation insulating pattern 245, but the embodiments are not limited thereto.

The landing pad LP may be disposed on the contact pattern BC. The landing pad LP may overlap the contact pattern BC in the third direction D3. The landing pad LP may be connected to the first channel pattern AP1 and the second channel pattern AP2 through the contact pattern BC. The landing pad LP may be disposed on the connecting part 231 of the contact pattern BC. The landing pad LP may make contact with the upper surface of the connecting part 231 of the contact pattern BC.

The landing pad LP includes a conductive material. The landing pad LP may include, for example, one or more of doped polysilicon, conductive metal nitride, conductive metal silicon nitride, metal carbonitride, conductive metal silicide, conductive metal oxide, two-dimensional material, metal, and/or metal alloy.

The data storage patterns DSP may each be disposed on the landing pads LP. The data storage patterns DSP may be connected to the first vertical part of the channel structure AP_ST and the second vertical part of the channel structure AP_ST. The data storage patterns DSP may be connected to each of the first and second channel patterns AP1 and AP2.

The data storage patterns DSP may be arranged in the form of a matrix along the first direction D1 and the second direction D2, as shown in FIG. 1. The data storage patterns DSP may completely or partially overlap the landing pads LP in the third direction D3. The data storage patterns DSP may make contact with all or part of the upper surfaces of the landing pads LP.

As an example, the data storage patterns DSP may be capacitors. The first channel pattern AP1 may be connected to the first capacitor. The second channel pattern AP2 may be connected to the second capacitor.

The data storage patterns DSP may include a capacitor dielectric film 253 interposed between the storage electrodes 251 and the plate electrode 255. In such a case, the storage electrode 251 may make contact with the landing pad LP. From a plan view perspective, the storage electrode 251 may have various shapes such as a circular shape, an oval shape, a rectangular shape, a square shape, a rhombic shape, and a hexagonal shape. The data storage patterns DSP may completely or partially overlap the landing pads LP. The data storage patterns DSP may make contact with all or part of the upper surfaces of the landing pads LP. The storage electrodes 251 may penetrate or extend into a cell upper etching stop film 247. The cell upper etching stop film 247 may be made of an insulating material.

In contrast, the data storage patterns DSP may be variable resistance patterns that may be switched between two resistance states by electrical pulses applied to the memory elements. For example, the data storage patterns DSP may include a phase-change material, perovskite compounds, transition metal oxide, magnetic materials, ferromagnetic materials or antiferromagnetic materials in which a crystalline state changes depending on the amount of current.

The contact pattern BC may be disposed on the channel structure AP_ST. The contact pattern BC may overlap the channel structure AP_ST in the third direction D3. The contact pattern BC may be on and at least partially cover the upper surface AP_US of the channel structure AP_ST.

Specifically, the contact pattern BC may be disposed on the first channel pattern AP1 and the second channel pattern AP2. The contact pattern BC may be disposed on the upper surface AP_US of the first channel pattern and the upper surface AP_US of the second channel pattern. The contact pattern BC may not be disposed on the connecting channel pattern AP_CP. The contact pattern BC may not overlap the connecting channel pattern AP_CP in the third direction D3.

The contact pattern BC may be on and at least partially cover a part of the side face of the channel structure AP_ST. The contact pattern BC may extend along the side faces of the first channel pattern AP1 and the second channel pattern AP2. For example, referring to FIG. 6, the contact pattern BC may extend along the side face AP_SW of the second channel pattern AP2. The contact pattern BC may be on and at least partially cover a part of the side face AP_SW of the second channel pattern AP2.

The contact pattern BC may partially overlap the insulating liner film 173 in the third direction D3. The contact pattern BC may overlap the first channel pattern AP1 and the second channel pattern AP2 in the third direction D3.

The width of the contact pattern BC may be greater than the first channel pattern AP1 and the second channel pattern AP2 in the first direction D1. Accordingly, the first channel pattern AP1 and the second channel pattern AP2 do not overlap the insulating liner film 173 in the third direction D3, but the contact pattern BC may partially overlap the insulating liner film 173 in the third direction D3.

The contact pattern BC may include a connecting part 231 and a protruding part 232. The contact pattern BC may have a “U” shape rotated by 180 degrees. The connecting part 231 and the protruding part 232 of the contact pattern BC may have a “U” shape rotated by 180 degrees.

The connecting part 231 may make contact with the landing pad LP. The connecting part 231 may be connected to the landing pad LP. The connecting part 231 may be disposed below the landing pad LP as shown in FIG. 4. The connecting part 231 may be disposed above the channel structure AP_ST as shown in FIG. 4. The connecting part 231 may be disposed on the upper surface AP_US of the channel structure AP_ST as shown in FIG. 4. The connecting part 231 may be disposed on the upper surface AP_US of the first channel pattern and the upper surface AP_US of the second channel pattern as shown in FIG. 4. In the first direction D1, the connecting part 231 may not overlap the first channel pattern AP1 and the second channel pattern AP2.

The connecting part 231 may be disposed between the insulating liner films 173 in the first direction D1. The connecting part 231 may be disposed between the gate insulating film GOX and the protruding insulating pattern 175 in the second direction D2.

The protruding part 232 may protrude from the connecting part 231 in the third direction D3. The protruding part 232 may protrude from the connecting part 231 toward the bit line BL and the cell lower insulating film 171 in the third direction D3. The protruding part 232 may cover a part of the side face AP_SW of the channel structure. The protruding part 232 may overlap a part of the side face AP_SW of the first channel pattern and the side face AP_SW of the second channel pattern.

Specifically, the protruding part 232 may be on and at least partially cover a part of the side faces AP_SW of the first channel pattern opposite to each other in the first direction D1. The protruding part 232 may be on and at least partially cover a part of the side face AP_SW of the second channel pattern opposite to each other in the first direction D1. The protruding part 232 may extend in the third direction D3 along the side face AP_SW of the channel structure. The protruding part 232 may overlap the first channel pattern AP1 and the second channel pattern AP2 in the first direction D1.

The protruding part 232 may be disposed on the insulating liner film 173. The protruding part 232 may be disposed between the first channel pattern AP1 and the insulating liner film 173, and between the second channel pattern AP2 and the insulating liner film 173 in the first direction D1. The protruding part 232 may be disposed between the gate insulating film GOX and the insulating liner film 173 in the second direction D2.

Although a thickness TH231 of the connecting part is shown as being smaller than the thickness TH232 of the protruding part, the embodiment is not limited thereto. For example, the thickness TH231 of the connecting part may be the same as the thickness TH232 of the protruding part.

The connecting part 231 may not overlap the first word line WL1 and the second word line WL2 in the second direction D2. The connecting part 231 may be disposed above the first word line WL1 and the second word line WL2 on the basis of the upper surface of the bit line BL, i.e., where the upper surface of the bit line BL provides a base reference plane. The lower surface 231BS of the connecting part may be disposed above the upper surface WL_US of the first word line and the second word line on the basis of the upper surface of the bit line BL, i.e., where the upper surface of the bit line BL provides a base reference plane.

The protruding part 232 may overlap the first word line WL1 and the second word line WL2 in the second direction D2. On the basis of the upper surface of the bit line BL, i.e., where the upper surface of the bit line BL provides a base reference plane, the lower surface 232BS of the protruding part may be disposed below the upper surface WL_US of the first word line and the second word line. However, embodiments are not limited thereto. For example, the protruding part 232 may not overlap the first word line WL1 and the second word line WL2 in the second direction D2. On the basis of the upper surface of the bit line BL, i.e., where the upper surface of the bit line BL provides a base reference plane, the lower surface 232BS of the protruding part may be disposed above the upper surfaces WL_US of the first word line and the second word line.

The lower surface of the contact pattern BC may refer to the lower surface 232BS of the protruding part. In the third direction D3, the lower surface 232BS of the protruding part may be disposed between the lower surface of the channel structure AP_ST and the upper surface AP_US of the channel structure. On the basis of the upper surface of the bit line BL, i.e., where the upper surface of the bit line BL provides a base reference plane, the lower surface 232BS of the protruding part may be disposed above the lower surface of the channel structure AP_ST, and may be disposed below the upper surface AP_US of the channel structure. The lower surface 232BS of the protruding part may not make contact with the upper surface of the cell lower insulating film 171. The lower surface 232BS of the protruding part may be spaced apart from the upper surface of the cell lower insulating film 171 in the third direction D3.

In the first direction D1, the width of the contact pattern BC may be greater than the width of the upper surface AP_US of the channel structure AP_ST. For example, referring to FIG. 6, in a cross-sectional view taken along the first direction D1, the protruding part 232 of the contact pattern BC may be on and at least partially cover the side face AP_SW of the channel structure. In the first direction D1, the outer wall of the contact pattern BC may protrude beyond the side face AP_SW of the channel structure. Therefore, in the first direction D1, the width W_BC of the contact pattern may be greater than the width W_AP of the upper surface AP_US of the channel structure.

In the second direction D2, the width of the contact pattern BC may not be greater than the width of the upper surface AP_US of the channel structure AP_ST. For example, referring to FIGS. 2 and 4, in a cross-sectional view taken along the second direction D2, the contact pattern BC may not cover the side face of the channel structure AP_ST. Specifically, in the cross-sectional view taken along the second direction D2, the connecting part 231 of the contact pattern BC may completely overlap the channel structure AP_ST in the third direction D3. In the cross-sectional view taken along the second direction D2, the side face of the connecting part 231 of the contact pattern BC may completely overlap the side face of the channel structure AP_ST in the third direction D3. Therefore, in the second direction D2, the width W231 of the contact pattern BC may be the same as the width of the upper surface AP_US of the channel structure AP_ST.

The contact pattern BC may overlap the insulating liner film 173 in the third direction D3. In the third direction D3, a part of the contact pattern BC may be disposed on the insulating liner film 173. A part of the contact pattern BC that does not overlap the first channel pattern AP1 and the second channel pattern AP2 in the third direction D3 may be disposed on the insulating liner film 173. Specifically, the protruding part 232 of the contact pattern BC may be disposed on the insulating liner film 173. The connecting part 231 that overlaps the protruding part 232 of the contact pattern BC in the third direction D3 may be disposed on the insulating liner film 173.

In the first direction D1, the contact pattern BC may be disposed between the insulating liner films 173. In the second direction D2, the contact pattern BC may be disposed between the protruding insulating pattern 175 and the gate insulating film GOX. The contact pattern BC may extend along the side wall of the protruding insulating pattern 175 in the third direction D3. The contact pattern BC may extend in the third direction D3 along the side wall of the gate insulating film GOX. In the third direction D3, the contact pattern BC may be disposed between the landing pad LP and the first channel pattern AP1 or the second channel pattern AP2.

The contact pattern BC includes a conductive material. The contact pattern BC may be include, for example, one or more of doped polysilicon, conductive metal nitride, conductive metal silicon nitride, metal carbonitride, conductive metal silicide, conductive metal oxide, two-dimensional material, metal, and/or metal alloy.

Since the contact pattern BC extends along the side faces of the first channel pattern AP1 and the second channel pattern AP2, the contact area between the contact pattern BC, the first channel pattern AP1 and second channel pattern AP2 may increase. Therefore, the resistance between the contact pattern BC, the first channel pattern AP1, and the second channel pattern AP2 may be reduced.

The insulating liner film 173 may be disposed between the contact patterns BC. In the first direction D1, the insulating liner film 173 may be disposed between the contact patterns BC. In the first direction D1, the insulating liner film 173 may be disposed between the first channel patterns AP1. In the first direction D1, the insulating liner film 173 may be disposed between the second channel patterns AP2.

From a plan view perspective, the insulating liner film 173 may be disposed between the protruding insulating patterns 175 in the first direction D1. The insulating liner film 173 may be disposed between the side faces of the protruding insulating pattern 175 opposite to each other in the first direction D1.

The insulating liner film 173 may be disposed between the side faces AP_SW of the first channel pattern AP1 opposite to each other in the first direction D1. The insulating liner film 173 may be disposed between the side faces AP_SW of the second channel pattern AP2 opposite to each other in the first direction D1. The insulating liner film 173 may not overlap the first channel pattern AP1 and the second channel pattern AP2 in the third direction D3.

From a plan view perspective, the insulating liner film 173 may be disposed between the first word line WL1 and the second word line WL2 in the second direction D2. The insulating liner film 173 may extend along the gate insulating film GOX and the cell lower insulating film 171 between the first word line WL1 and the second word line WL2 in the second direction D2. The insulating liner film 173 may extend along the upper surface of the cell lower insulating film 171. The insulating liner film 173 may extend along the lower surface and side faces of the insulating filling film 174. The insulating liner film 173 may be on and at least partially cover the lower surface and side faces of the insulating filling film 174.

The insulating liner film 173 may border and at least partially surround the protruding part 232 of the contact pattern BC. The insulating liner film 173 may be on and at least partially cover the side faces and lower surface 232BS of the protruding part 232 of the contact pattern BC. That is, the protruding part 232 of the contact pattern BC may be disposed inside the insulating liner film 173.

In the first direction D1, the insulating liner film 173 may be disposed between the contact patterns BC. For example, referring to FIG. 6, the insulating liner film 173 may at least partially fill in the space between the contact patterns BC.

Further, in the first direction D1, the insulating liner film 173 may be disposed between the channel structures AP_ST. For example, referring to FIG. 6, the insulating liner film 173 may at least partially fill the space between the second channel patterns AP2.

The insulating liner film 173 may include a first portion 173a and a second portion 173b. The first portion 173a may be disposed on the second portion 173b. The first portion 173a may extend from the second portion 173b to the part between the contact patterns BC. The first portion 173a of the insulating liner film 173 may be disposed between the contact patterns BC. The first portion 173a of the insulating liner film 173 may at least partially fill the space between the contact patterns BC.

The first portion 173a may be disposed between the contact patterns BC spaced apart in the first direction D1. The first portion 173a may be disposed between the connecting parts 231 spaced apart in the first direction D1. The first portion 173a may be disposed between the protruding parts 232 spaced apart in the first direction D1. The first portion 173a may extend in the third direction D3 along the side face of the contact pattern BC.

The second portion 173b may be disposed below the first portion 173a. The second portion 173b may be connected to the first portion 173a. The second portion 173b of the insulating liner film 173 may be disposed below the contact pattern BC. The second portion 173b of the insulating liner film 173 may be disposed between the channel structures AP_ST spaced apart in the first direction D1. For example, the second portion 173b may be disposed between second active patterns AP2 spaced apart in the first direction D1.

The width of the first portion 173a may be less than the width of the second portion 173b. That is, in the first direction D1, the distance between the contact patterns BC adjacent to each other may be less than the distance between the channel structures AP_ST adjacent to each other.

The insulating filling film 174 may be disposed on the insulating liner film 173. The insulating filling film 174 may at least partially fill the lower part of the pad separation insulating pattern 235 on the insulating liner film 173. The insulating filling film 174 may be bordered or at least partially surrounded by the insulating liner film 173. The insulating filling film 174 may extend along an inner face and a lower surface of the insulating liner film 173.

In the first direction D1, the insulation filling film 174 may overlap the protruding insulating pattern 175. In the first direction D1, the insulating filling film 174 may not overlap the first channel pattern AP1 and the second channel pattern AP2. Furthermore, in the first direction D1, the insulating filling film 174 may not overlap the contact pattern BC. In the first direction D1, the insulating liner film 173 overlaps the contact pattern BC, but the insulating filling film 174 may not overlap the contact pattern BC. Therefore, referring to FIG. 6, only the insulating liner film 173 is disposed between the contact patterns BC, and the insulating filling film 174 may not be disposed.

In the second direction D2, the insulating filling film 174 may not overlap the contact pattern BC. The insulating filling film 174 may not overlap the contact pattern BC in the third direction D3. The insulating filling film 174 of the contact pattern BC may not be disposed. The insulating liner film 173 below overlaps the contact pattern BC in the third direction D3, but the insulating filling film 174 may not overlap the contact pattern BC.

The insulating liner film 173 and the insulating filling film 174 may each include an insulating material. The insulating liner film 173 and the insulating filling film 174 may each include one or more of silicon nitride (SiN), silicon oxynitride (SiON), silicon oxide (SiO₂), silicon carbonitride (SiCN), silicon oxycarbonitride (SiOCN), and a combination thereof. For example, the insulating liner film 173 may include silicon nitride, and the insulating filling film 174 may include silicon oxide.

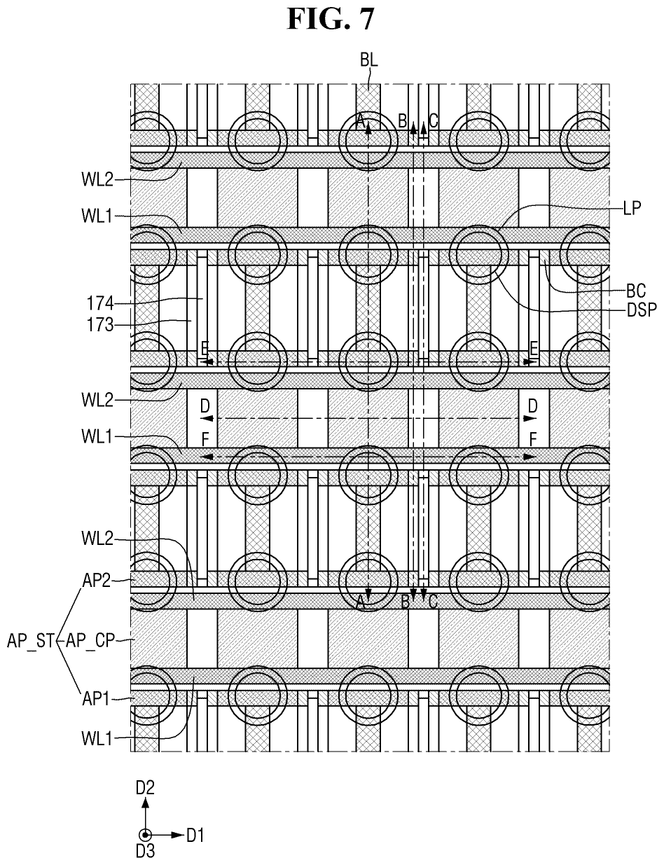

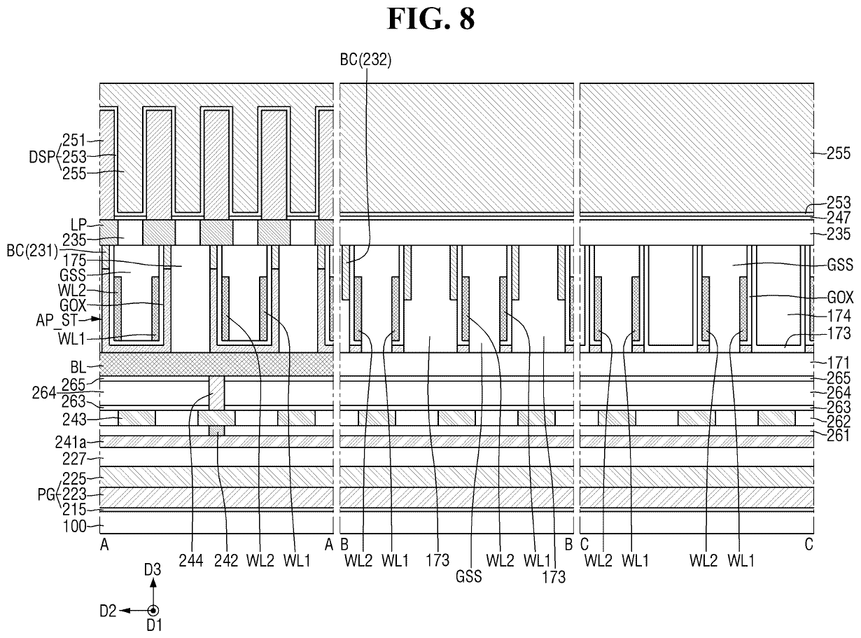

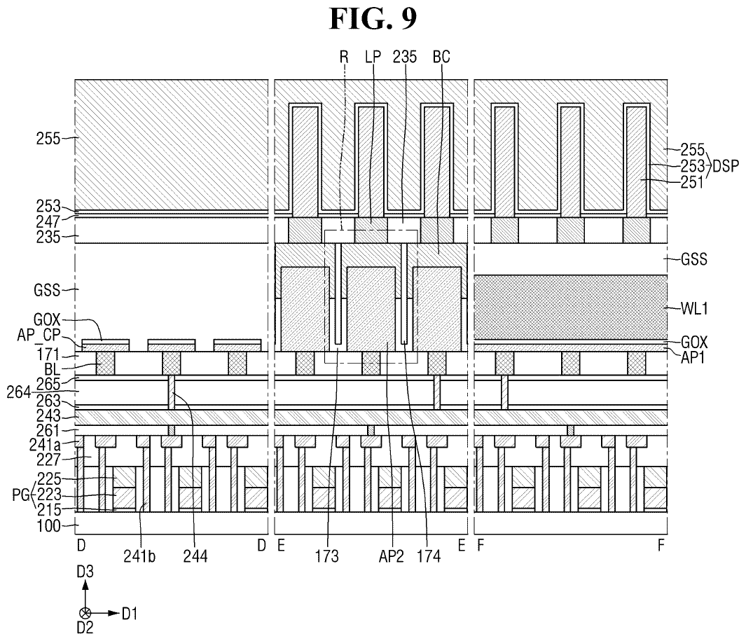

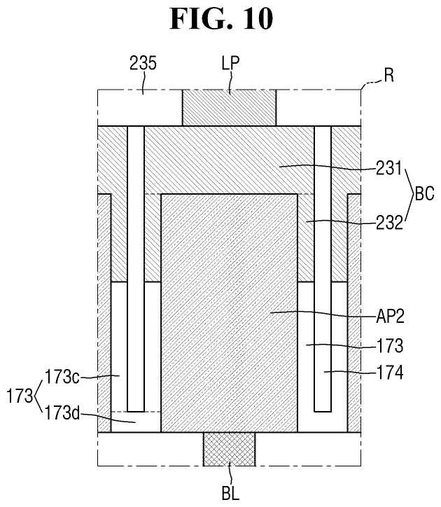

FIG. 7 is a layout diagram that illustrates a semiconductor memory device according to some other embodiments. FIG. 8 is a cross-sectional view taken along lines A-A, B-B, and C-C of FIG. 7. FIG. 9 is a cross-sectional view taken along lines D-D, E-E, and F-F of FIG. 7. FIG. 10 is an enlarged view showing a portion R of FIG. 9. For convenience of explanation, the explanation will focus on features that are different from those described with reference to FIGS. 1 to 6.

Referring to FIGS. 7 to 10, the insulating filling film 174 may overlap the first channel pattern AP1 and the second channel pattern AP2 in the first direction D1. Further, the insulating filling film 174 may overlap the contact pattern BC in the first direction D1.

For example, referring to the C-C cross section of FIG. 8, the thickness of the side part of the insulating liner film 173 extending along the gate insulating film GOX may be less than the thickness of the lower part of the insulating liner film 173 extending along the upper surface of the cell lower insulating film 171.

Referring to FIG. 7 in comparison with FIG. 1, from a plan view perspective, the insulating filling film 174 at least partially surrounded by the insulating liner film 173 increases in width in the second direction D2. Therefore, the insulating filling film 174 may overlap the first channel pattern AP1, the second channel pattern AP2, and the contact pattern BC in the first direction D1.

Specifically, referring to FIG. 10, the insulating filling film 174 may extend in the third direction D3 between the contact patterns BC adjacent in the first direction D1. The insulating filling film 174 may at least partially fill the space between the contact patterns BC adjacent in the first direction D1. The insulating filling film 174 may make contact with the connecting part 231 and the protruding part 232 of the contact pattern BC.

The insulating liner film 173 may extend along the side face of the second channel pattern AP2 below the connecting part 231. The insulating liner film 173 may have a “U” shape below the connecting part 231. The insulating liner film 173 may have a “U” shape between the second channel patterns AP2 in the first direction D1.

Although not shown, the insulating liner film 173 may similarly extend along the side face of the first channel pattern AP1 below the connecting part 231. The insulating liner film 173 may have a “U” shape between the first channel patterns AP1 in the first direction D1.

For example, the insulating liner film 173 may include a third portion 173c and a fourth portion 174d. The third portion 173c may be disposed on the upper surface of the cell lower insulating film 171. The third portion 173c may extend along the upper surface of the cell lower insulating film 171. The third portion 173c may be disposed below the insulating filling film 174.

The fourth portion 174d may protrude from the third portion 173c in the third direction D3. The fourth portion 174d may extend along the side face of the second channel pattern AP2. The fourth portion 174d may be disposed in the side part of the insulating filling film 174.

The insulating filling film 174 may be disposed on the insulating liner film 173. The insulating filling film 174 may be bordered or at least partially surrounded by the insulating liner film 173 below the connecting part 231.

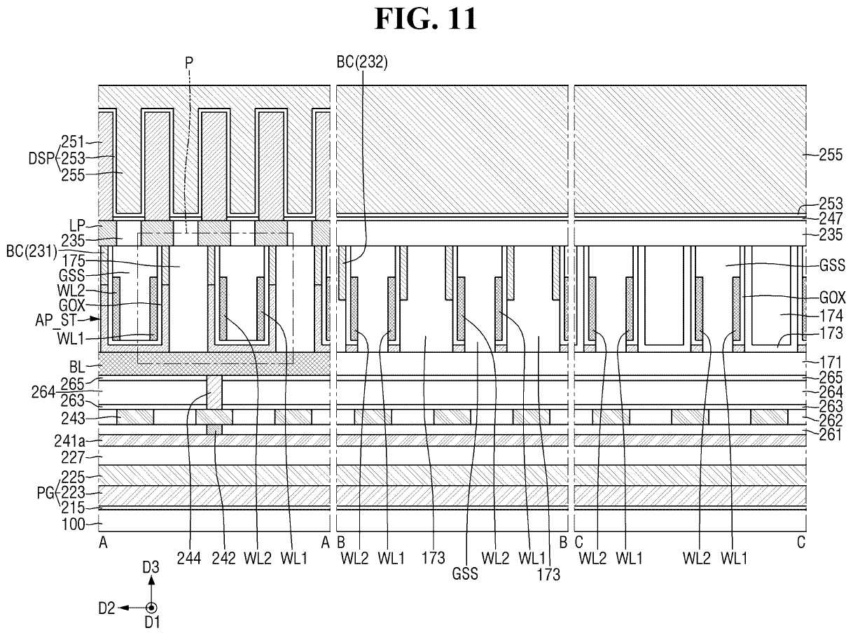

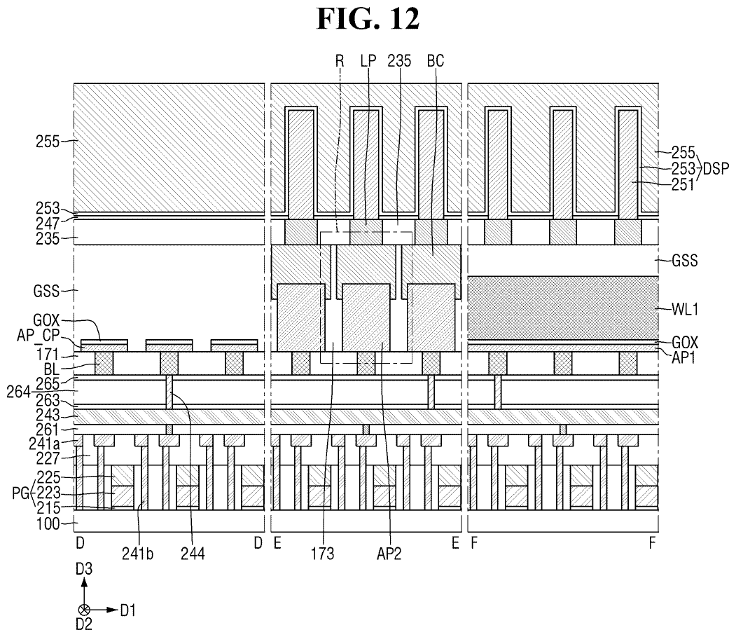

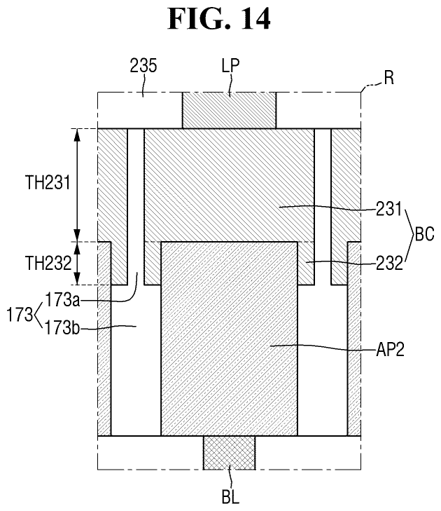

FIGS. 11 to 14 are diagrams that illustrate a semiconductor memory device according to some other embodiments. For convenience of explanation, the explanation will focus on features that are different from those described with reference to FIGS. 1 to 6.

Referring to FIGS. 11 to 14, the connecting part 231 may overlap the first word line WL1 and the second word line WL2 in the second direction D2. On the basis of the upper surface of the bit line BL, i.e., where the upper surface of the bit line BL provides a base reference plane, the lower surface 231BS of the connecting part may be disposed below the upper surface WL_US of the first word line and the second word line.

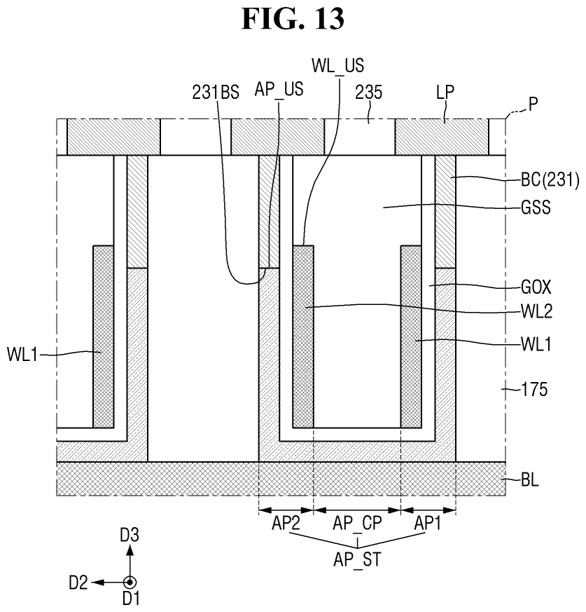

The upper surface WL_US of the first word line and the upper surface WL_US of the second word line may be disposed above the upper surface AP_US of the channel structure AP_ST as shown in FIG. 13. A thickness TH231 of the connecting part may be greater than a thickness TH232 of the protruding part. However, the embodiments are not limited thereto. For example, even if the connecting part 231 overlaps the first word line WL1 and the second word line WL2 in the second direction D2, the thickness TH231 of the connecting part may be less than the thickness TH232 of the protruding part.

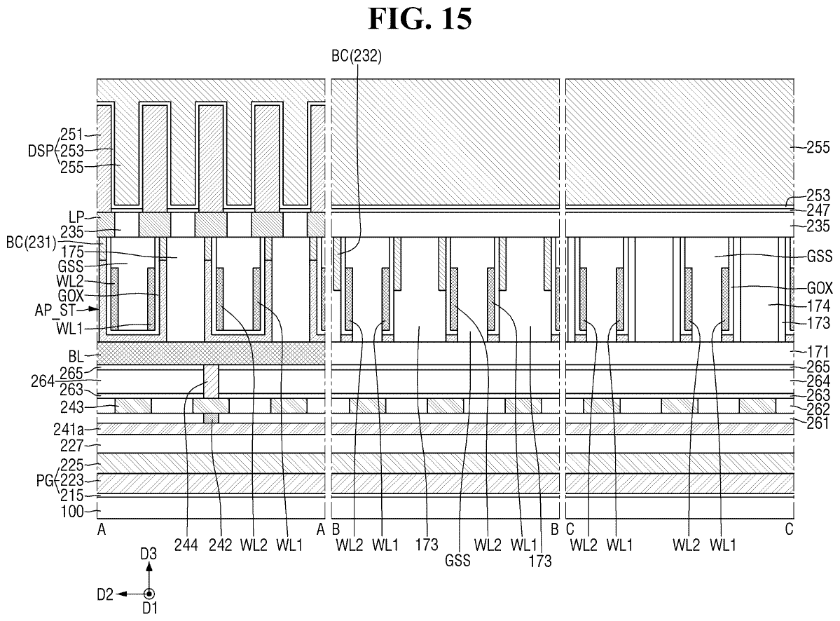

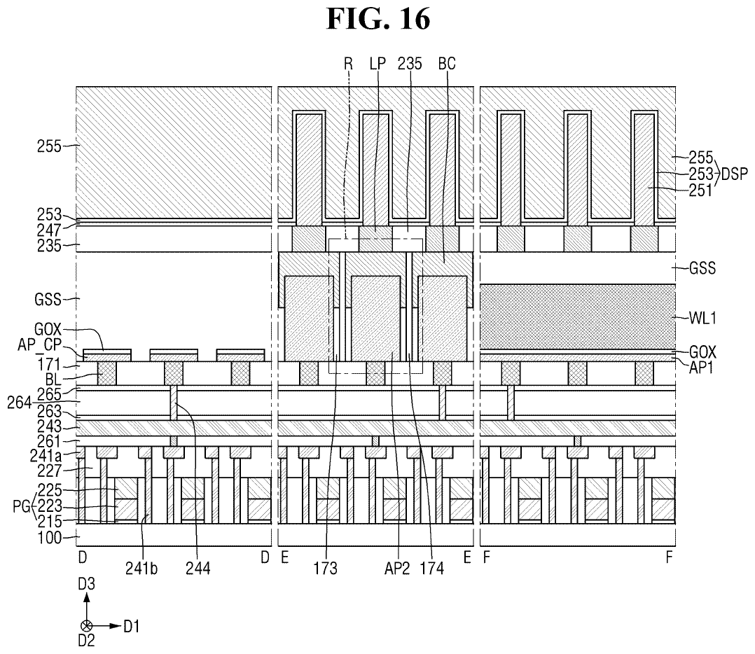

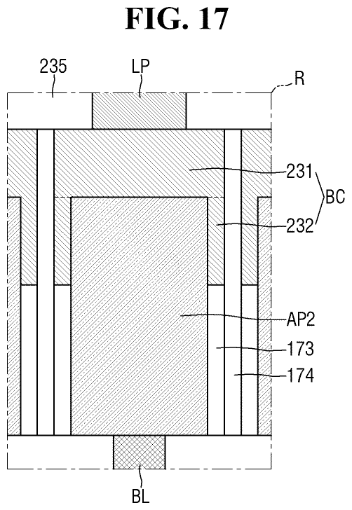

FIGS. 15 to 17 are diagrams that illustrate a semiconductor memory device according to some other embodiments. For convenience of explanation, the explanation will focus on features that are different from those described with reference to FIGS. 1 to 6.

Referring to FIGS. 15 to 17, the insulating liner film 173 may not extend along the lower surface of the insulating filling film 174. The insulating liner film 173 and the insulating filling film 174 may not overlap in the third direction D3. The insulating liner film 173 may not cover the lower surface of the insulating filling film 174. The insulating liner film 173 may extend only along the side face of the insulating filling film 174. The insulating liner film 173 may not extend along the upper surface of the cell lower insulating film 171.

The lower surface of the insulating filling film 174 may make contact with an upper surface of the cell lower insulating film 171. The lower surface of the insulating filling film 174 may be coplanar with the lower surface of the second channel pattern AP2. Between the first channel pattern AP1 or the second channel pattern AP2 in the first direction D1, the insulating filling film 174 may extend from the upper surface of the cell lower insulating film 171 to the lower surface of the pad separation insulating pattern 235 in the third direction D3. The lower surface of the insulating filling film 174 may be coplanar with the lower surface of the protruding insulating pattern 175.

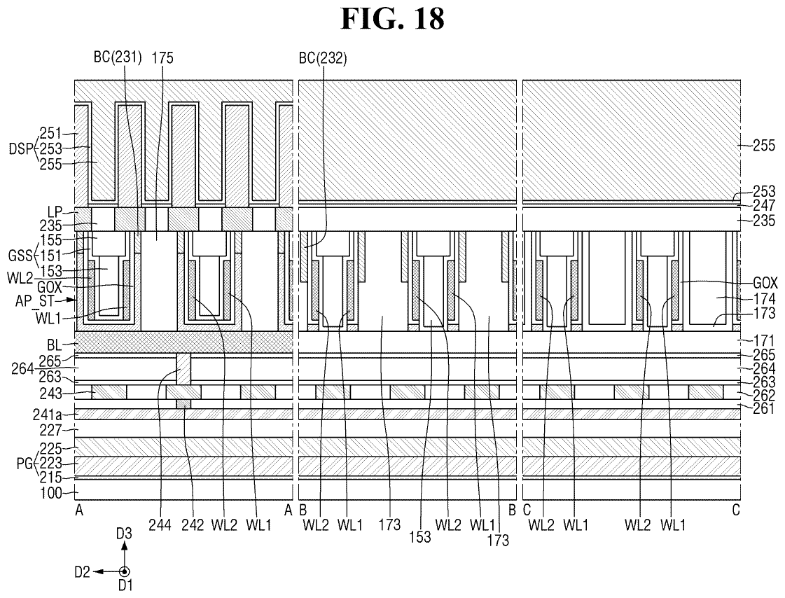

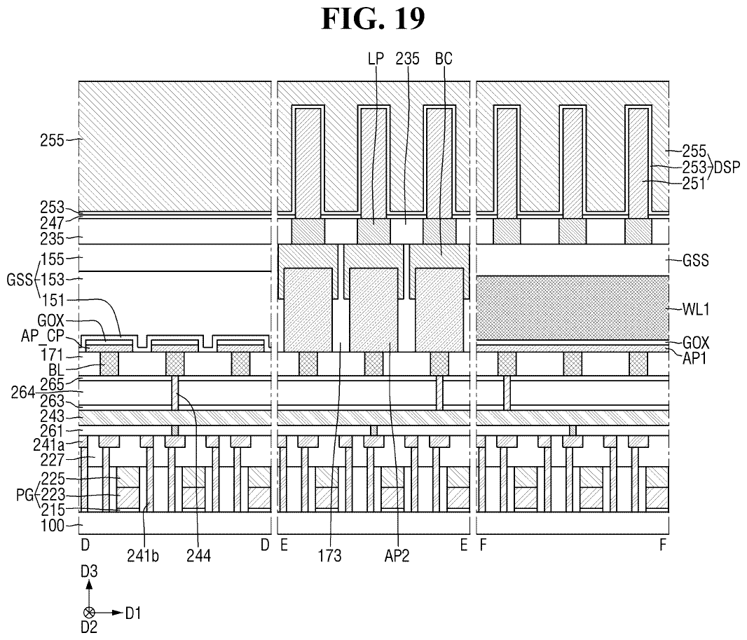

FIGS. 18 and 19 are diagrams that illustrate the semiconductor memory device according to some other embodiments. For convenience of explanation, the explanation will focus on features that are different from those described with reference to FIGS. 1 to 6.

Referring to FIGS. 18 and 19, the gate separation pattern GSS may include multiple films. The gate separation pattern GSS may include a gate separation liner 151, a gate separation filling film 153, and a gate separation capping film 155. The gate separation liner 151 may extend along upper surfaces of the first and second word lines WL1 and WL2 and along outer walls of the first and second word lines WL1 and WL2. The gate separation liner 151 may extend along the horizontal part of the channel structure AP_ST. The gate separation liner 151 may make contact with the connecting channel pattern AP_CP. The gate separation liner 151 may extend along the gate insulating film GOX that protrudes beyond the upper surfaces of the first and second word lines WL1 and WL2. Unlike the shown example, the gate separation liner 151 may not extend along the gate insulating film GOX that protrudes beyond the upper surfaces WL_US of the first and second word lines WL1 and WL2.

The gate separation filling film 153 may be disposed on the gate separation liner 151. The gate separation filling film 153 is disposed between the first and second word lines WL1 and WL2. The gate separation filling film 153 may overlap the first and second word lines WL1 and WL2 in the second direction D2.

A gate separation capping film 155 may be disposed on the gate separation filling film 153. The gate separation capping film 155 may be disposed on the first and second word lines WL1 and WL2. The gate separation capping film 155 may not overlap the first and second word lines WL1 and WL2 in the second direction D2. The gate separation liner 151, the gate separation filling film 153, and the gate separation capping film 155 may each be made up of an insulating material.

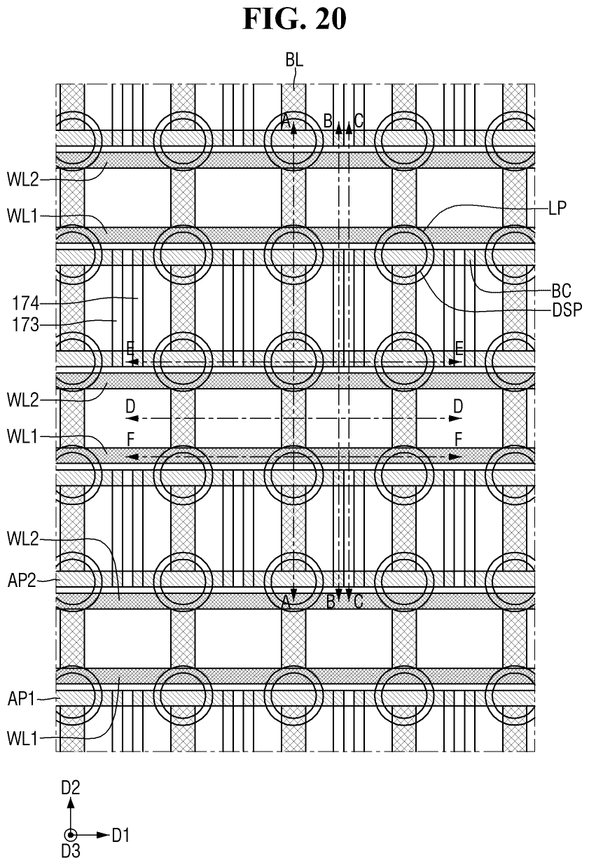

FIGS. 20 to 24 are diagrams that illustrate a semiconductor memory device according to some other embodiments. For convenience of explanation, the explanation will focus on features that are different from those described with reference to FIGS. 1 to 6.

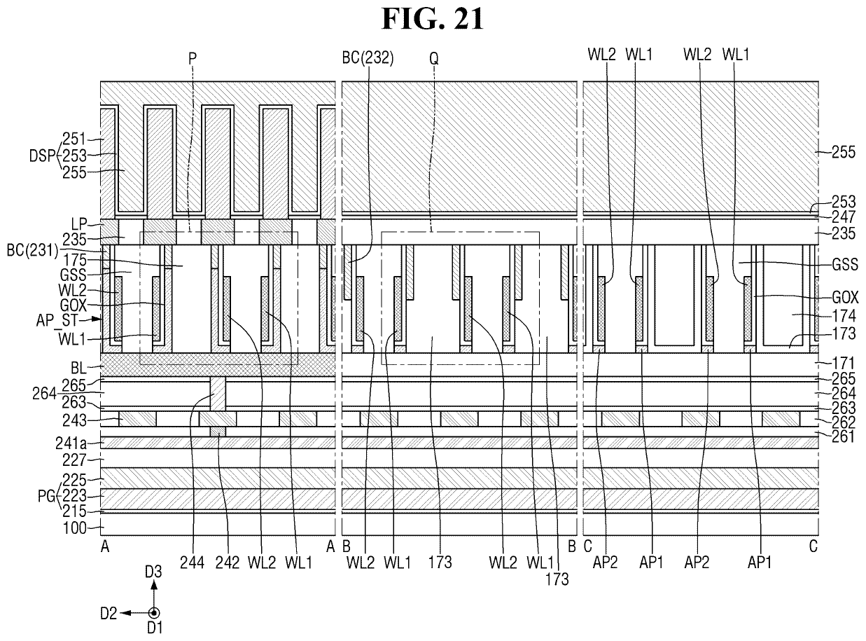

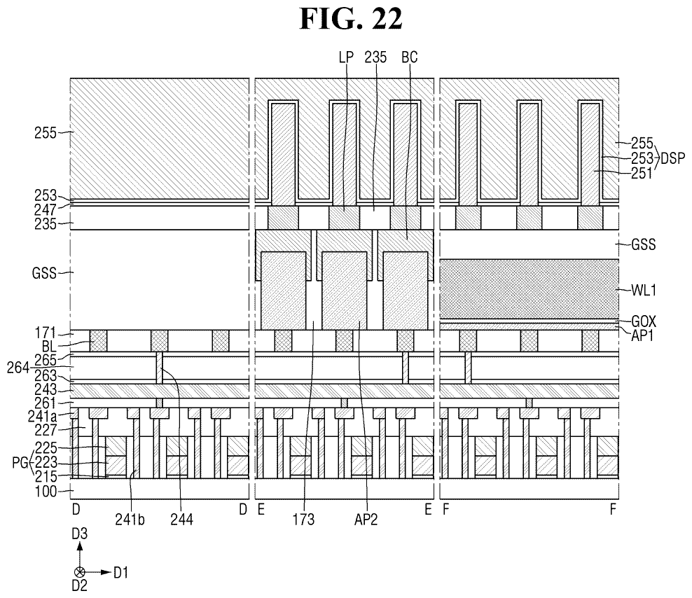

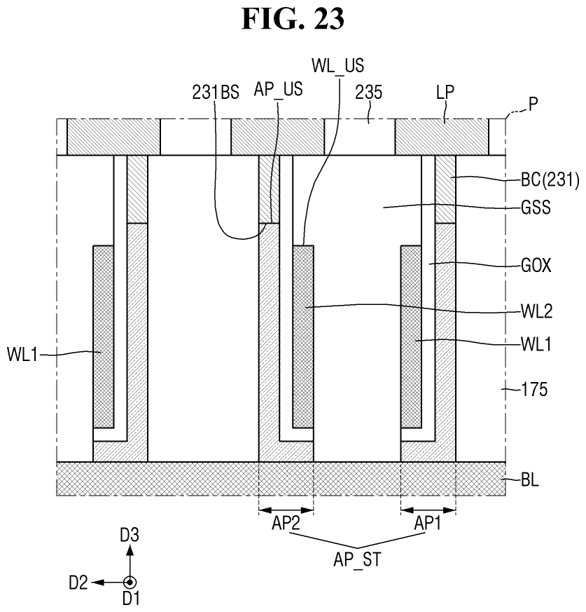

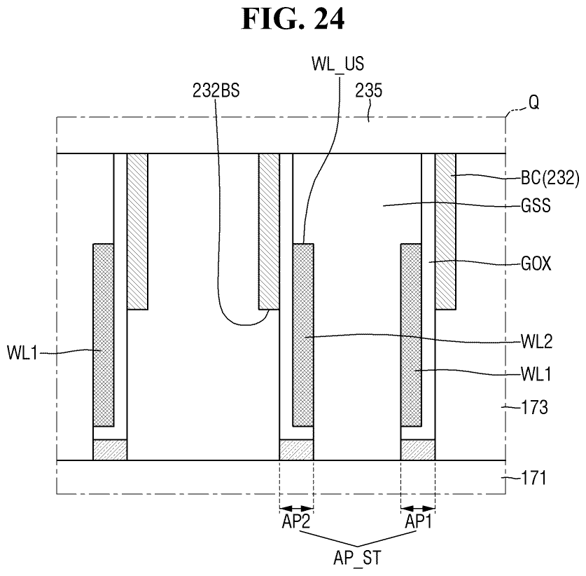

For reference, FIG. 20 is a layout diagram that illustrates a semiconductor memory device according to some embodiments. FIG. 21 is a cross-sectional view taken along lines A-A, B-B, and C-C of FIG. 20. FIG. 22 is a cross-sectional view taken along lines D-D, E-E, and F-F of FIG. 20. FIG. 23 is an enlarged view of a portion P of FIG. 21. FIG. 24 is an enlarged view showing a portion Q of FIG. 21.

Referring to FIGS. 20 to 24, in the semiconductor memory device according to some embodiments, the first channel pattern AP1 and the second channel pattern AP2, which are spaced apart in the second direction D2, are not connected.

The channel structure AP_ST may not be disposed between the first word line WL1 and the second word line WL2 that face each other with the gate separation pattern GSS interposed therebetween.

The first channel pattern AP1 may include a horizontal part extending along the upper surface of the bit line BL, and a vertical part extending along the side wall of the protruding insulating pattern 175. The vertical part of the first channel pattern AP1 may protrude from the horizontal part of the first channel pattern AP1 in the third direction D3.

The second channel pattern AP2 may include a horizontal part extending along the upper surface of the bit line BL, and a vertical part extending along the side wall of the protruding insulating pattern 175. The vertical part of the second channel pattern AP2 may protrude from the horizontal part of the second channel pattern AP2 in the third direction D3.

The gate separation pattern GSS may make contact with the upper surface of the bit line BL. The horizontal part of the first channel pattern AP1 and the horizontal part of the second channel pattern AP2 may be spatially separated by the gate separation pattern GSS. The gate separation pattern GSS may make contact with the upper surface of the cell lower insulating film 171.

The lower surface of the gate separation pattern GSS may be coplanar with the lower surface of the insulating liner film 173. The lower surface of the gate separation pattern GSS may be coplanar with the lower surface of the protruding insulating pattern 175.

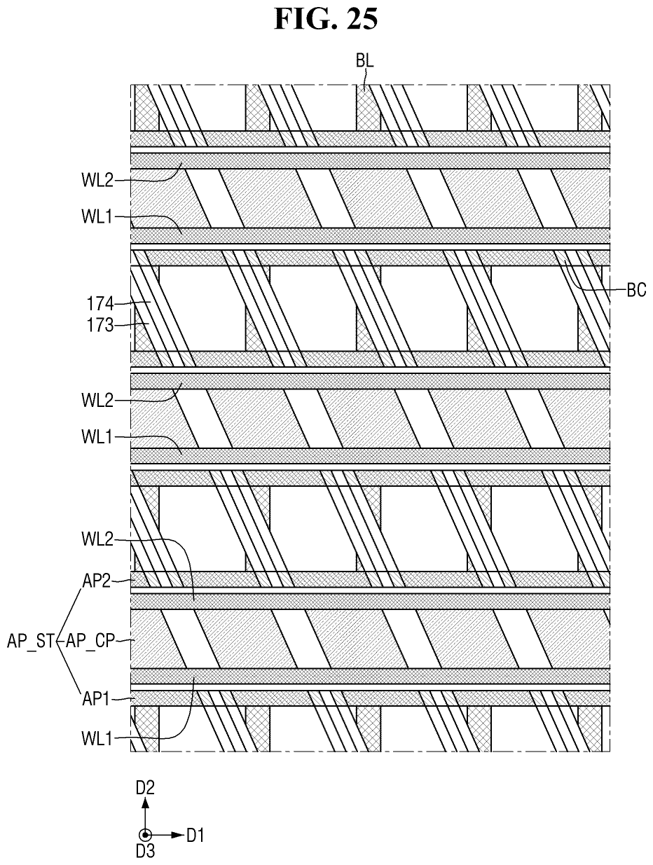

FIGS. 25 to 28 are diagrams that illustrate a semiconductor memory device according to some other embodiments, respectively. For convenience of explanation, the explanation will focus on features that are different from those described with reference to FIGS. 1 to 6.

Referring to FIG. 25, in the semiconductor memory device according to some embodiments, the first channel pattern AP1 and the second channel pattern AP2 may be arranged alternately in a diagonal direction with respect to the first direction D1 and the second direction D2. Here, the diagonal direction may be parallel to the upper surface of the substrate 100.

The channel structure AP_ST may be twisted in the diagonal direction. From a plan view perspective, the first channel pattern AP1, the second channel pattern AP2, and the connecting channel pattern AP_CP may each have a parallelogram shape or a rhombus shape.

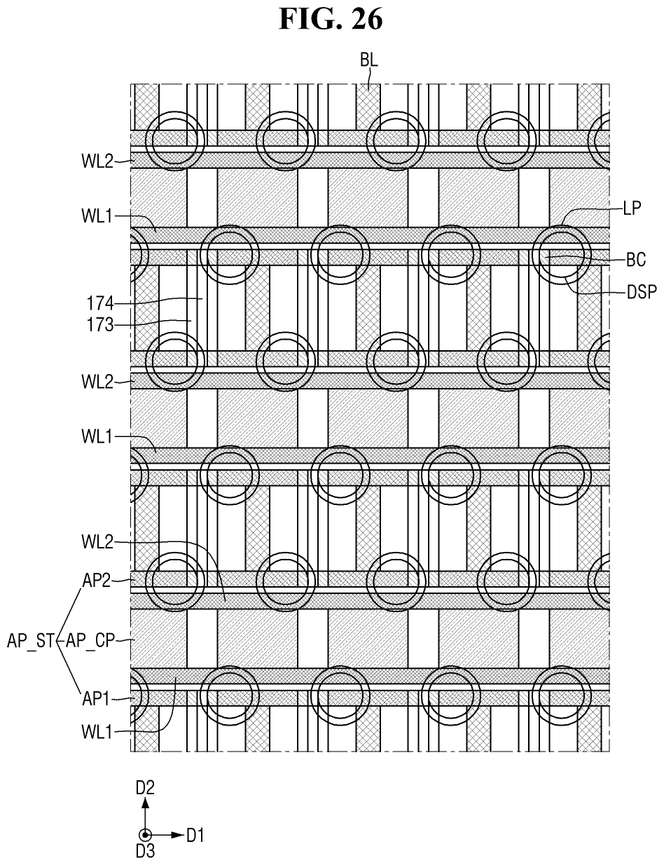

Referring to FIG. 26, in the semiconductor memory device according to some embodiments, the landing pads LP and the data storage patterns DSP may be arranged in a zigzag or honeycomb shape from a plan view perspective.

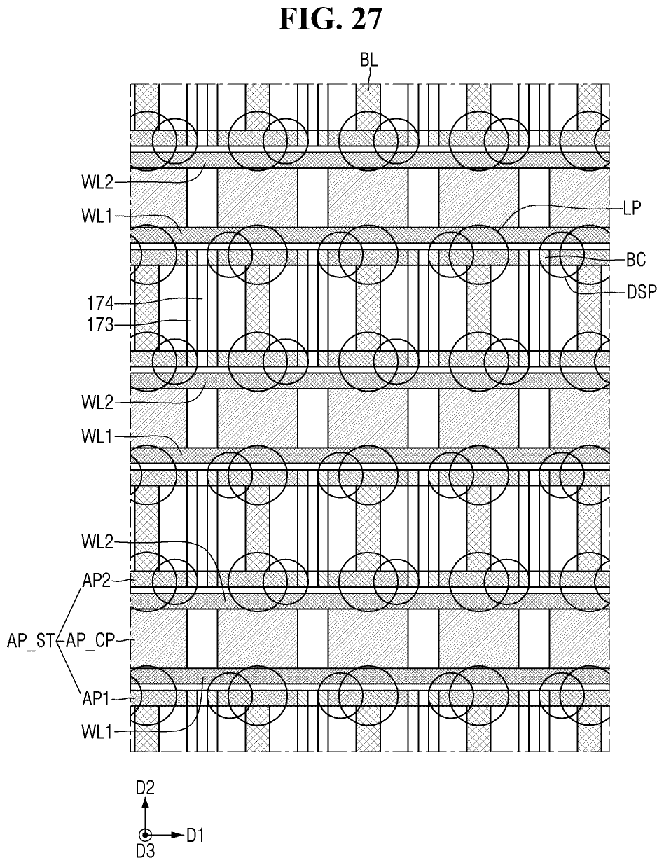

Referring to FIG. 27, in the semiconductor memory device according to some embodiments, the data storage patterns DSP may be disposed to be at least partially out from under the landing pads LP from a plan view perspective.

Each data storage pattern DSP may make contact with a part of the landing pad LP.

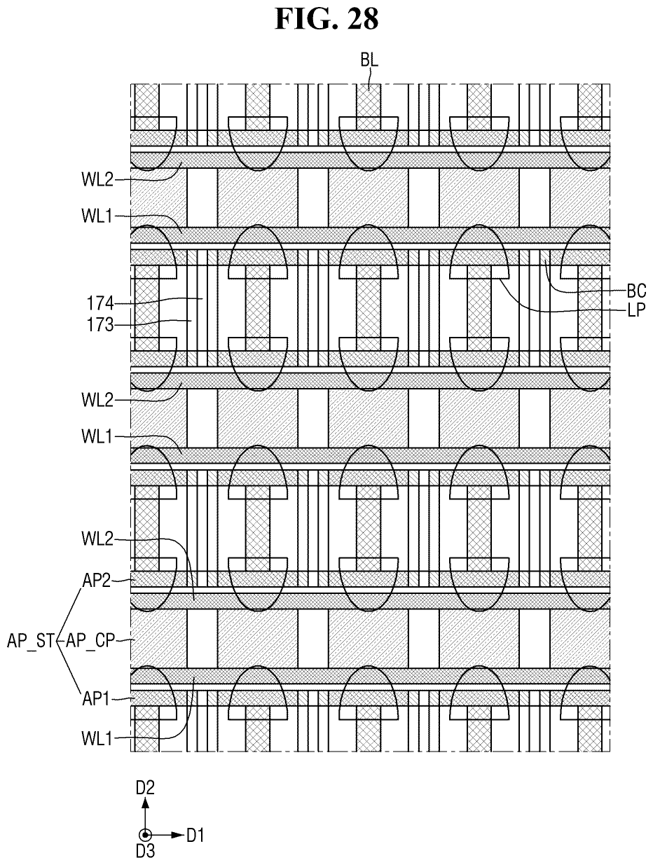

Referring to FIG. 28, in the semiconductor memory device according to some embodiments, each of the landing pads LP disposed on the first channel pattern AP1 and the second channel pattern AP2 may have a semi-circular shape or a semi-elliptical shape from a plan view perspective.

From a plan view perspective, the landing pads LP may be disposed symmetrically to each other.

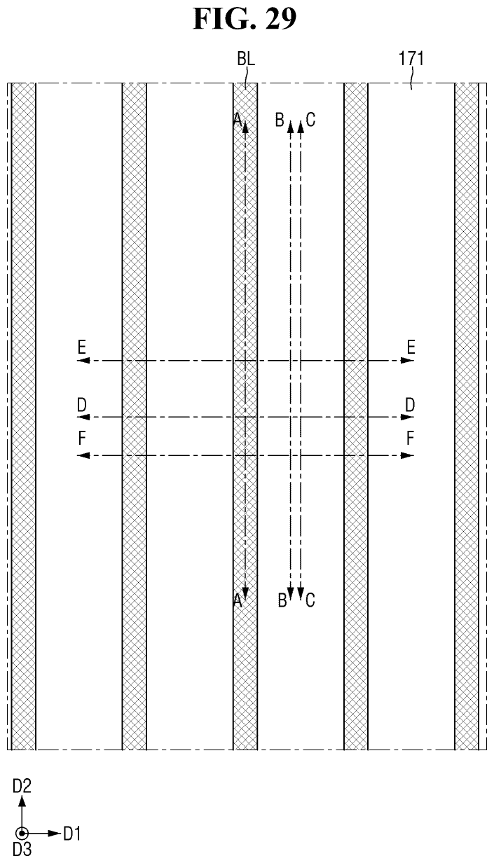

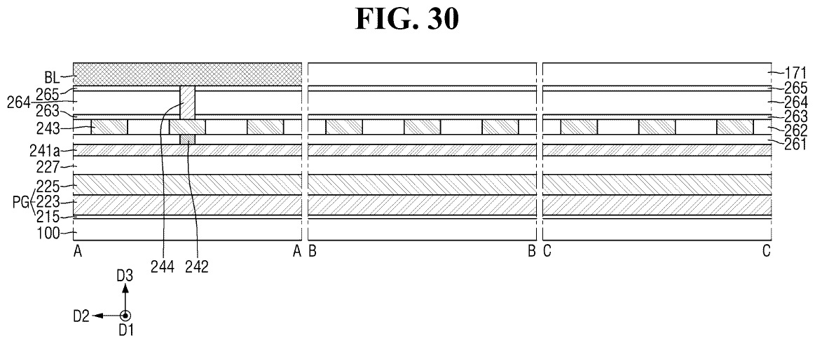

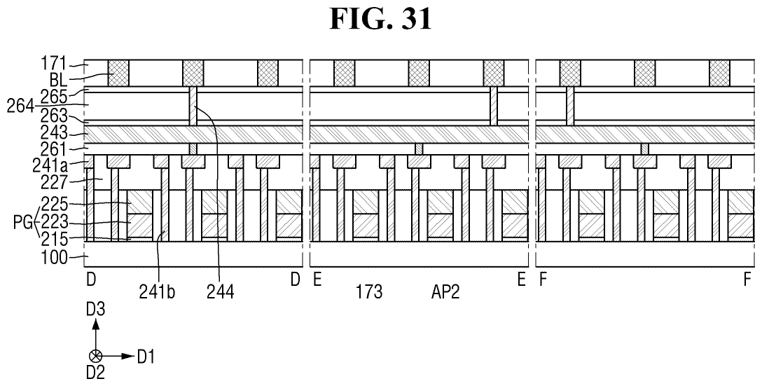

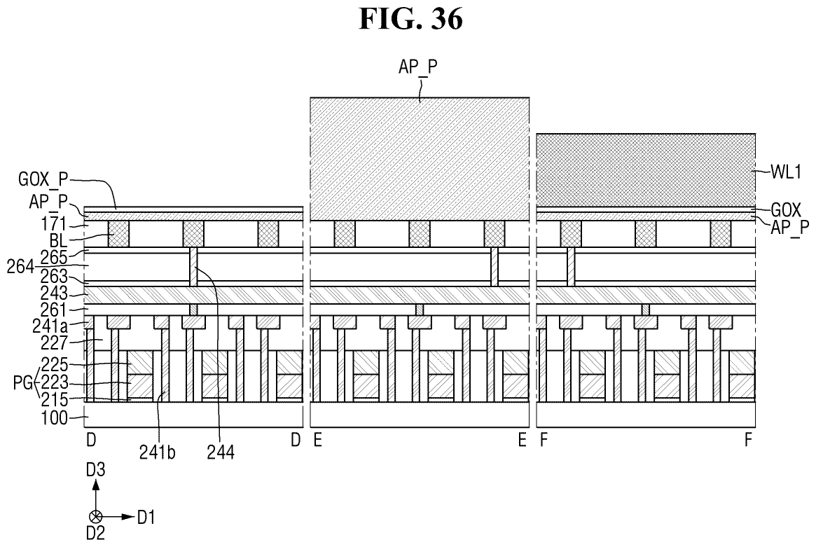

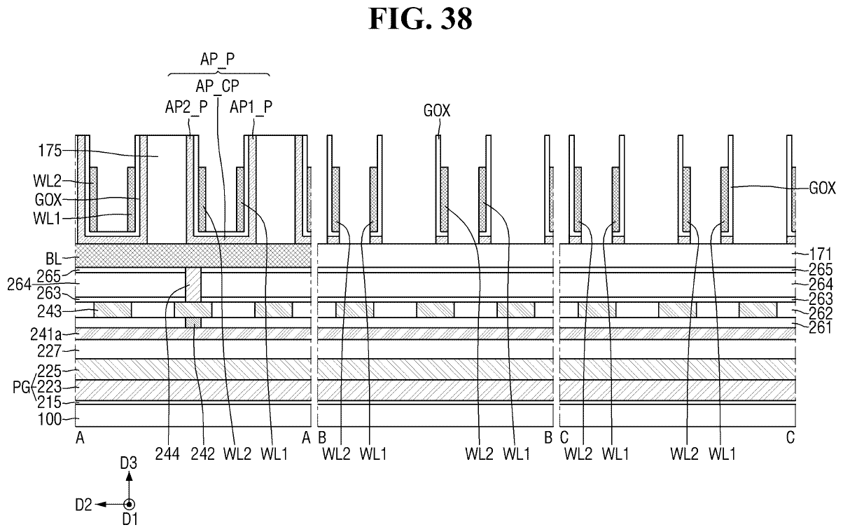

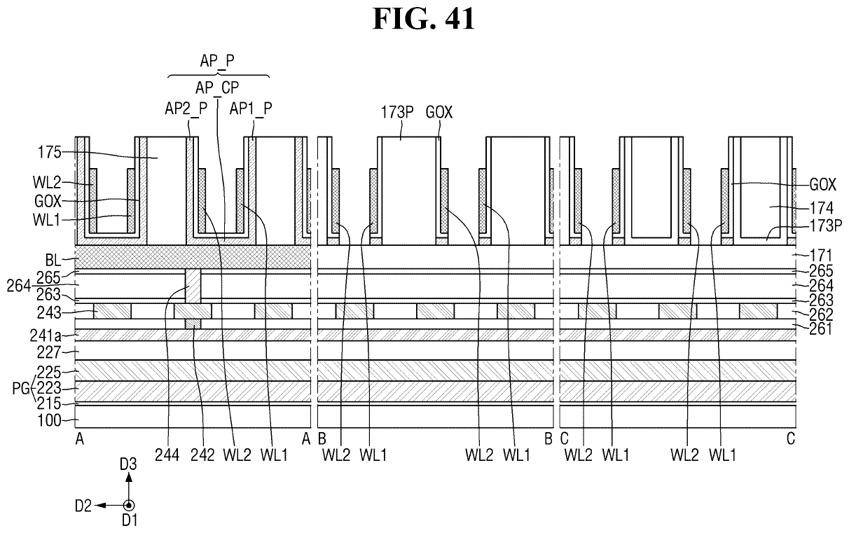

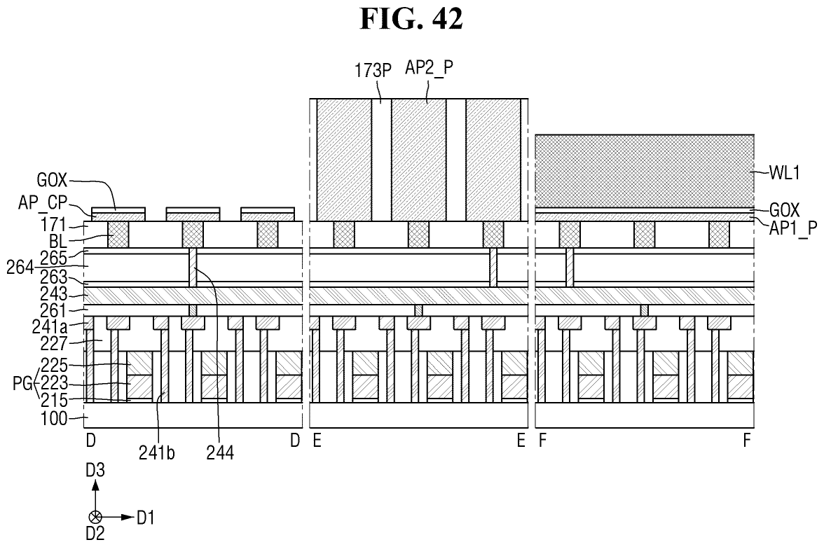

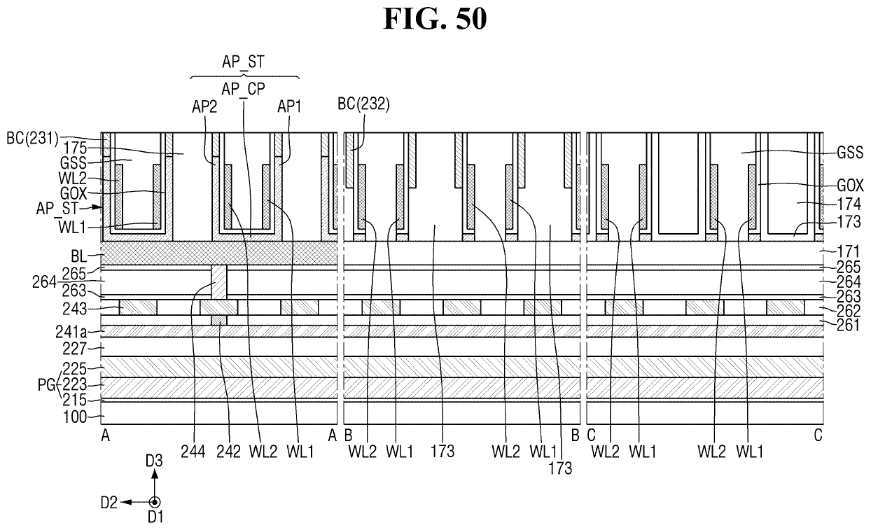

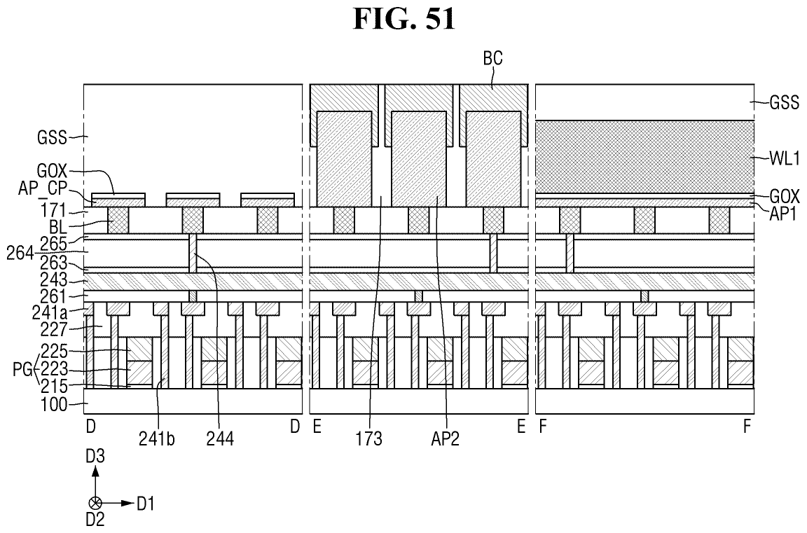

FIGS. 29 to 51 are diagrams of intermediate structures that illustrate a method for fabricating the semiconductor memory device according to some embodiments.

Referring to FIGS. 29 to 31, a peri-gate structure PG may be formed on the substrate 100.

The first peri-wiring line 241a and the peri-contact plug 241b may be formed on the substrate 100.

The peri-upper insulating films 261, 262, 263, 264, and 265 may be sequentially formed on the first peri-wiring line 241a and the peri-contact plug 241b. The second peri-wiring line 243, the peri-via plug 242, and the cell connection plug 244 may be formed inside the peri-upper insulating films 261, 262, 263, 264, and 265.

Subsequently, the bit lines BL may be formed on the fifth peri-upper insulating film 265. The bit line BL may extend lengthwise in the second direction D2 on the substrate 100. The cell lower insulating film 171 may be formed on the fifth peri-upper insulating film 265. The cell lower insulating film 171 may expose the upper surface of the bit line BL.

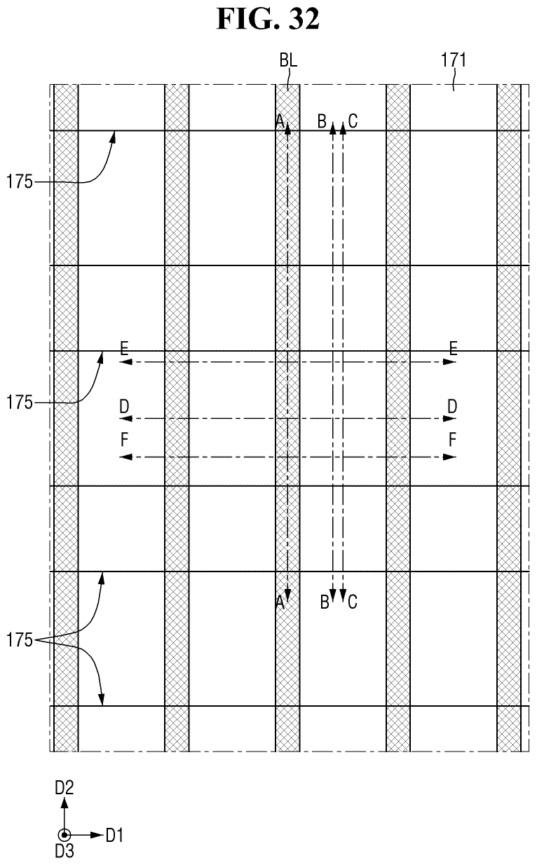

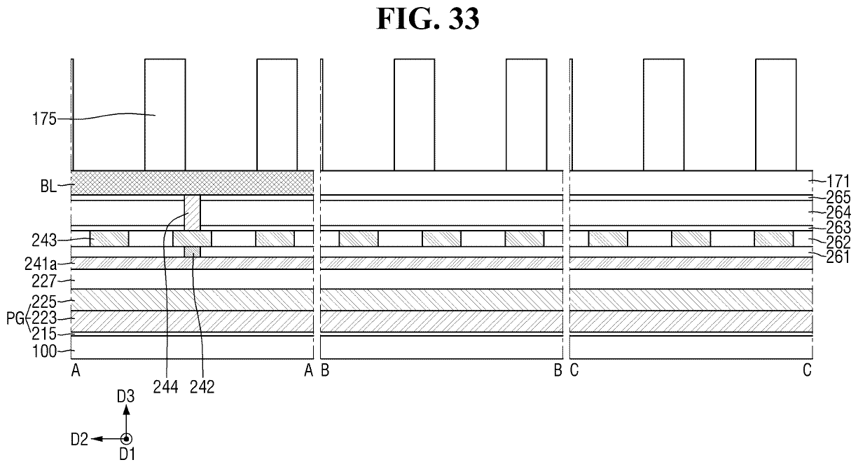

Referring to FIGS. 32 and 33, the protruding insulating pattern 175 may be formed on the substrate 100. Specifically, the protruding insulating pattern 175 may be formed on the bit line BL and the cell lower insulating film 171.

The protruding insulating pattern 175 may extend in the first direction D1. The protruding insulating patterns 175 may be spaced apart from each other in the second direction D2.

From a plan view perspective, the protruding insulating pattern 175 may intersect the bit line BL. From a cross-sectional viewpoint, the protruding insulating pattern 175 may protrude from the bit line BL in the third direction D3.

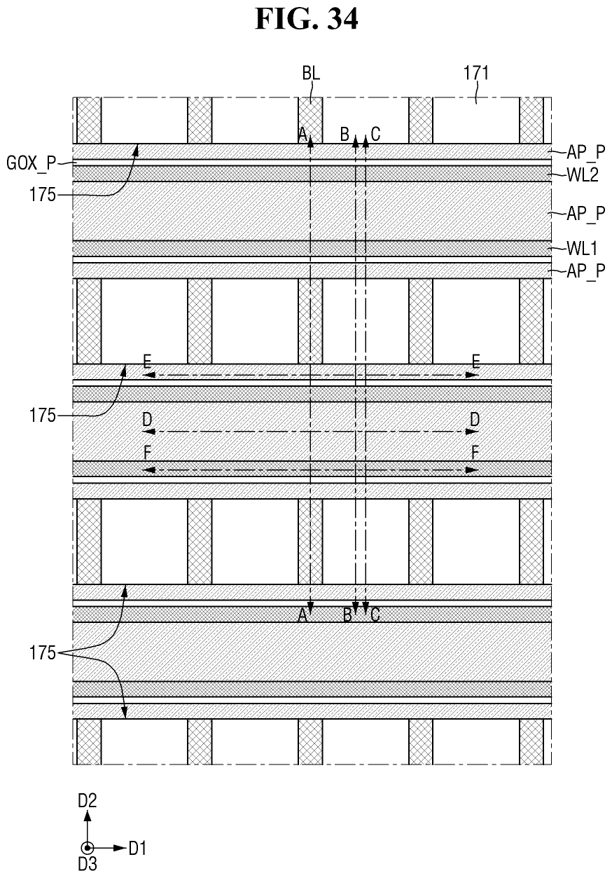

Referring to FIGS. 34 to 36, the pre-channel pattern AP_P, the pre-gate insulating film GOX_P, the first word line WL1, and the second word line WL2 may be formed.

The pre-channel pattern AP_P may be formed on the bit line BL and the protruding insulating pattern 175. The pre-channel pattern AP_P may extend along the upper surface of the bit line BL and the profile of the protruding insulating pattern 175. The pre-channel pattern AP_P may be on and at least partially cover the upper surface of the protruding insulating pattern 175.

The pre-gate insulating film GOX_P may be formed on the pre-channel pattern AP_P. The pre-gate insulating film GOX_P may extend along the profile of the pre-channel pattern AP_P. The pre-gate insulating film GOX_P may be on and at least partially cover the upper surface of the protruding insulating pattern 175.

The first word line WL1 and the second word line WL2 may be formed on the pre-gate insulating film GOX_P. The first word line WL1 and the second word line WL2 may be formed apart from each other in the second direction D2 on the pre-gate insulating film GOX_P. The first word line WL1 and the second word line WL2 may be formed below the upper surface of the protruding insulating pattern 175 on the basis of the upper surface of the bit line BL, i.e., where the upper surface of the bit line BL provides a base reference plane. The first word line WL1 and the second word line WL2 may be formed below the upper surface of the pre-channel pattern AP_P on the basis of the upper surface of the bit line BL, i.e., where the upper surface of the bit line BL provides a base reference plane.

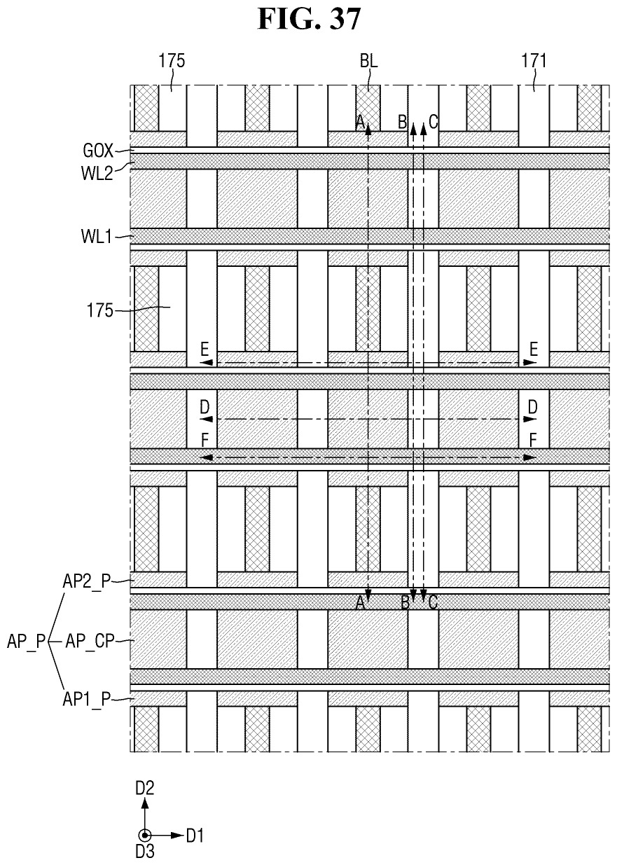

Referring to FIGS. 37 to 39, the protruding insulating pattern 175 and the pre-channel pattern AP_P may be cut in the first direction D1.

The protruding insulating patterns 175 may be separated between the bit lines BL to be spaced apart in the first direction D1. In the first direction D1, the upper surface of the cell lower insulating film 171 may be exposed between the protruding insulating patterns 175.

The first pre-channel patterns AP1_P may be spaced apart from each other in the first direction D1. The second pre-channel patterns AP2_P may be spaced apart from each other in the first direction D1. The pre-channel pattern AP_P may be separated to form the connecting channel pattern AP_CP. The connecting channel patterns AP_CP may be spaced apart from each other in the first direction D1. From a plan view perspective, the connecting channel pattern AP_CP may be disposed between the first word line WL1 and the second word line WL2. In the first direction D1, the upper surface of the cell lower insulating film 171 may be exposed between the connecting channel patterns AP_CP.

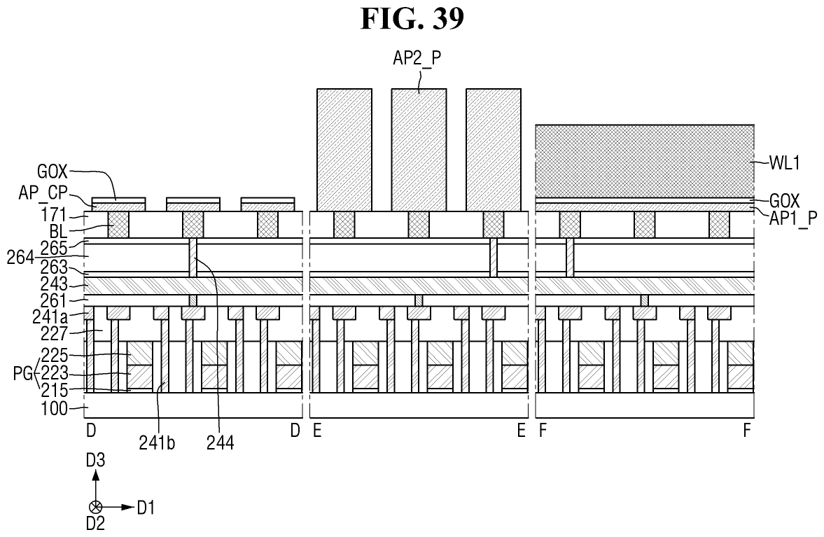

The pre-channel pattern AP_P disposed below the first word line WL1 and the second word line WL2 may not be cut in the first direction D1. For example, referring to the E-E cross section of FIG. 39, the pre-channel pattern AP_P may extend in the first direction D1 under the first word line WL1.

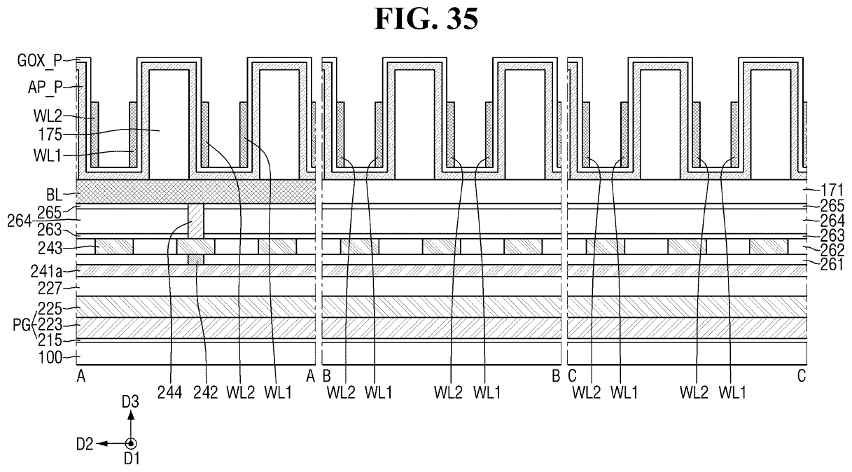

The pre-channel pattern AP_P and the pre-gate insulating film (GOX_P of FIG. 35) that at least partially cover the upper surface of the protruding insulating pattern 175 may be removed. As a result, the upper surface of the protruding insulating pattern 175 is exposed, and the gate insulating film GOX may be formed. The upper surface of the gate insulating film GOX may be coplanar with the upper surface of the protruding insulating pattern 175. The gate insulating film GOX may not be cut in the first direction D1. The gate insulating film GOX may extend in the first direction D1.

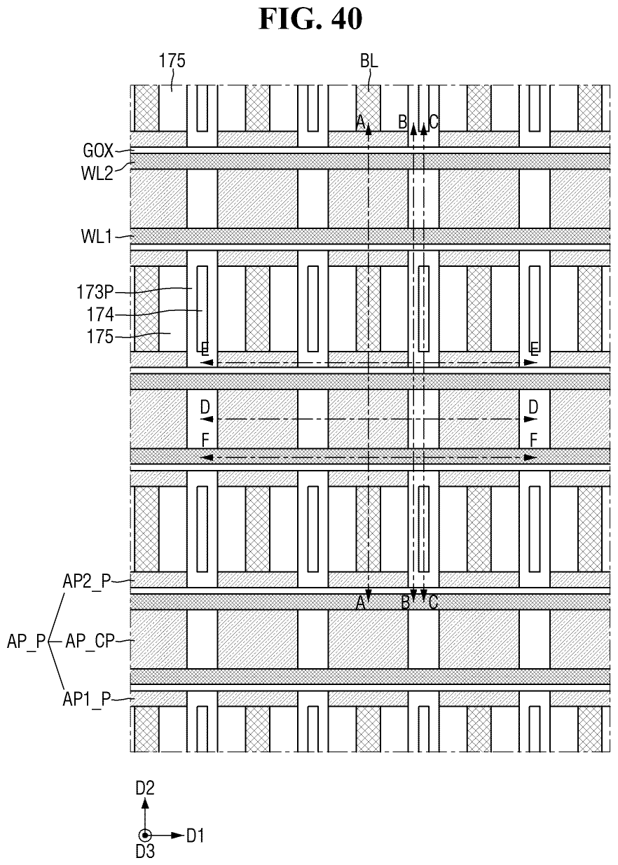

Referring to FIGS. 40 to 42, the pre-insulating liner film 173P and the insulating filling film 174 may be formed.

In the first direction D1, the pre-insulating liner film 173P may be disposed between the protruding insulating patterns 175. In the first direction D1, the pre-insulating liner film 173P may at least partially fill a space between the first pre-channel patterns AP1_P. The pre-insulating liner film 173P may extend in the third direction D3 along the side face of the first pre-channel pattern AP1_P.

In the first direction D1, the pre-insulating liner film 173P may at least partially fill a space between the second pre-channel patterns AP2_P. The pre-insulating liner film 173P may extend in the third direction D3 along the side face of the second pre-channel pattern AP2_P.

The pre-insulating liner film 173P may extend along the side walls of the gate insulating film GOX facing each other in the second direction D2 and the upper surface of the cell lower insulating film 171. The upper surface of the pre-insulating liner film 173P may be coplanar with the upper surface of the protruding insulating pattern 175. The upper surface of the pre-insulating liner film 173P may be coplanar with the upper surface of the gate insulating film GOX.

The insulation filling film 174 may be formed on the pre-insulation liner film 173P. The upper surface of the insulating filling film 174 may be coplanar with the upper surface of the pre-insulating liner film 173P. The pre-insulating liner film 173P may border or at least partially surround the insulating filling film 174.

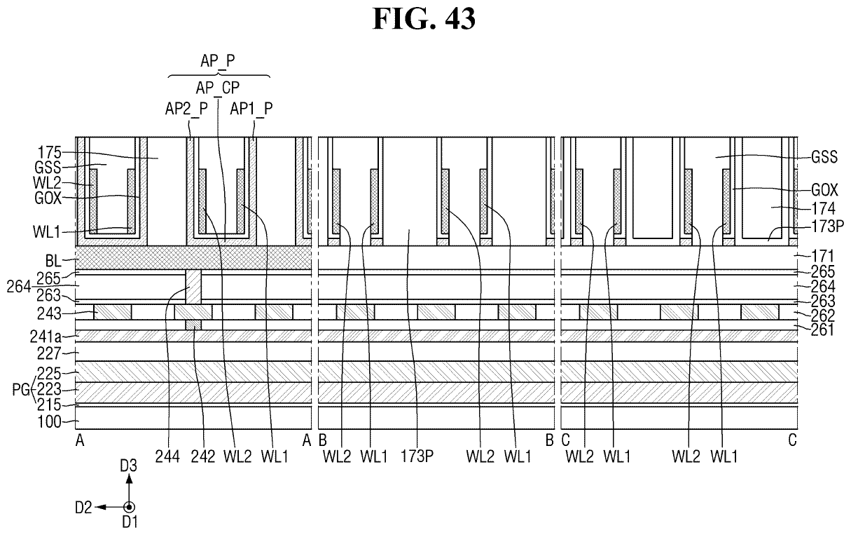

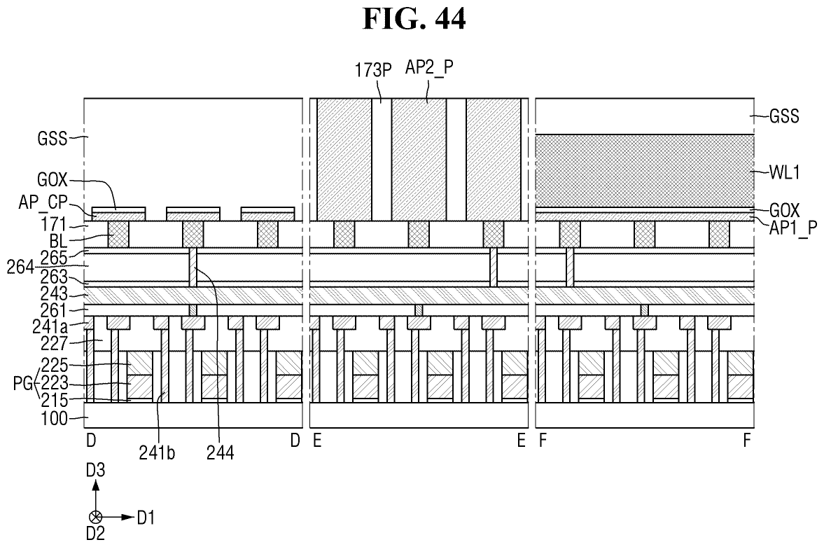

Referring to FIGS. 43 and 44, the gate separation pattern GSS may be formed.

The gate separation pattern GSS may be formed on the cell lower insulating film 171, the channel structure AP_ST, the gate insulating film GOX, the first word line WL1, and the second word line WL2. The upper surface of the gate separation pattern GSS may be coplanar with the upper surfaces of the gate insulating film GOX and the pre-insulating liner film 173P. The gate separation pattern GSS may be formed on the cell lower insulating film 171 between the connecting channel patterns AP_CP spaced apart in the first direction D1. The gate separation pattern GSS may be on and at least partially cover the connecting channel pattern AP_CP and the gate insulating film GOX.

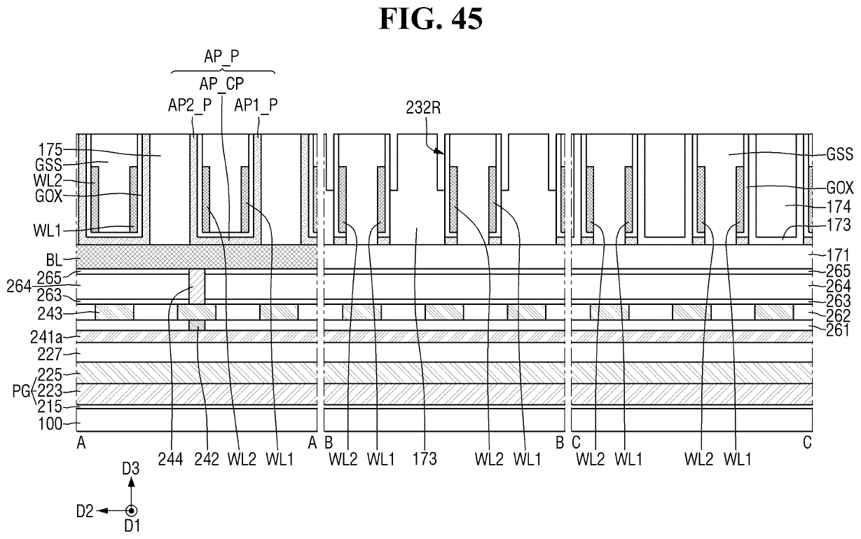

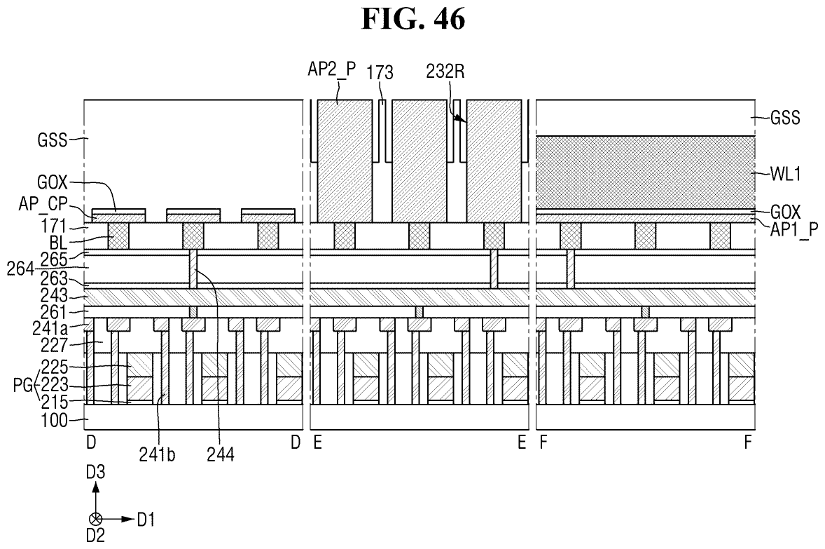

Referring to FIGS. 45 and 46, a protruding recess 232R may be formed.

The protruding recess 232R may be formed on the upper surface of the pre-insulating liner film 173P. A part of the pre-insulating liner film 173P may be removed.

In the first direction D1, the protruding recess 232R may be formed on the side faces of the first pre-channel pattern AP1_P and the second pre-channel pattern AP2_P. A part of the pre-insulating liner film 173P that at least partially covers the side faces of the first pre-channel pattern AP1_P and the second pre-channel pattern AP2_P may be removed. When the protruding recess 232R is formed, a part of the side faces of the first pre-channel pattern AP1_P and the second pre-channel pattern AP2_P may be exposed.

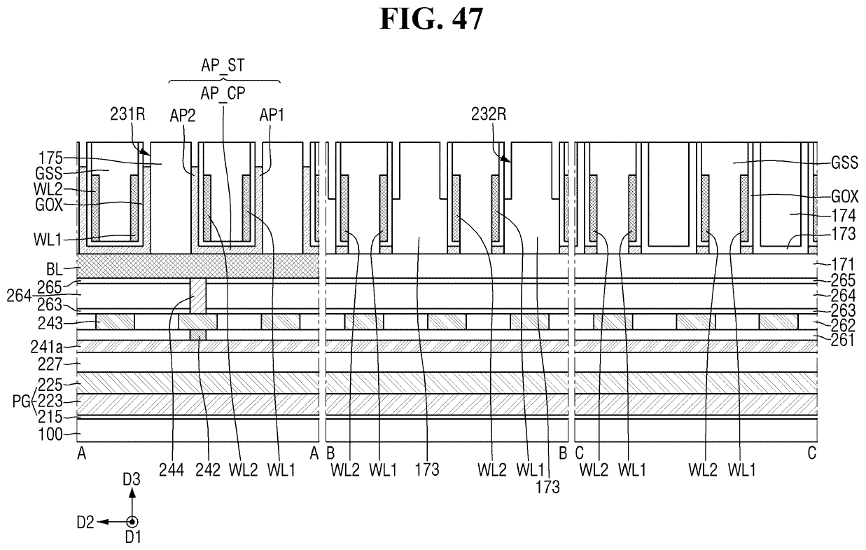

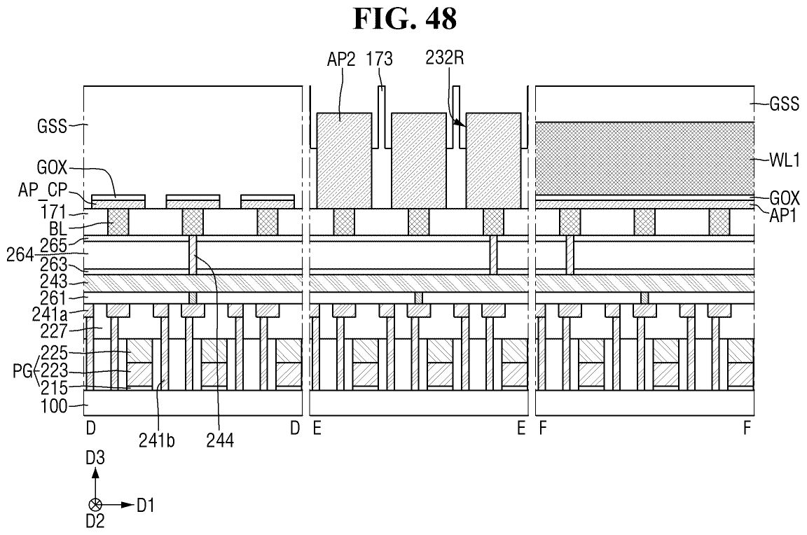

Referring to FIGS. 47 and 48, a connecting recess 231R may be formed.

A part of the first pre-channel pattern (AP1_P of FIGS. 45 and 46) and a part of the second pre-channel pattern (AP2_P of FIGS. 45 and 46) may be removed. The upper parts of the first pre-channel pattern (AP1_P of FIGS. 45 and 46) and the second pre-channel pattern (AP2_P of FIGS. 45 and 46), which have the same height of the upper surface as that of the protruding insulating pattern 175, may be removed. Accordingly, the first channel pattern AP1 and the second channel pattern AP2 may be formed. When the connecting recess 231R is formed, the upper surface of the first channel pattern AP1 and the upper surface of the second channel pattern AP2 may be disposed below the upper surface of the protruding insulating pattern 175 as shown in FIG. 47.

In the third direction D3, the insulating liner film 173 may protrude beyond the first channel pattern AP1 and the second channel pattern AP2. When the upper parts of the first pre-channel pattern (AP1_P of FIGS. 45 and 46) and the second pre-channel pattern (AP2_P of FIGS. 45 and 46) are partially removed by forming the connecting recess 231R, the upper surface of the insulating liner film 173 may be disposed to be higher than the upper surface of the first channel pattern AP1 and the upper surface of the second channel pattern AP2 as shown in FIG. 48.

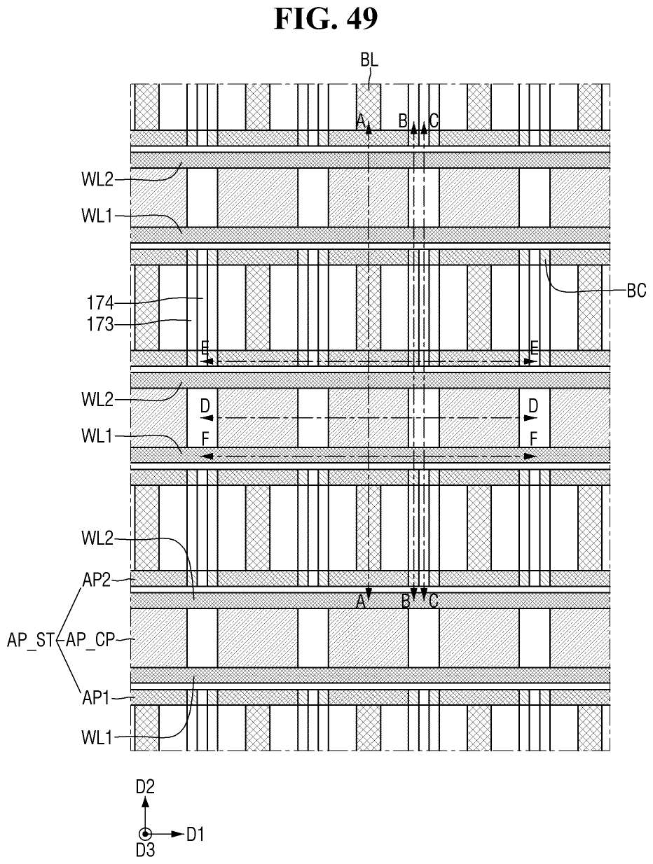

Referring to FIGS. 49 to 51, a contact pattern BC may be formed.

The contact pattern BC may be formed inside the connecting recess (231R of FIG. 47) and the protruding recess (232R of FIGS. 47 and 48). The contact pattern BC may be on and at least partially cover a part of the side faces of the first channel pattern AP1 and the second channel pattern AP2. The contact pattern BC may at least partially fill the connecting recess (231R of FIG. 47) and the protruding recess (232R of FIGS. 47 and 48).

In concluding the detailed description, those skilled in the art will appreciate that many variations and modifications may be made to the preferred embodiments without substantially departing from the principles of the present inventive concept. Therefore, the disclosed preferred embodiments of the invention are used in a generic and descriptive sense only and not for purposes of limitation.

What is claimed is:

1. A semiconductor memory device comprising:
a first bit line extending in a first direction on a substrate;
a word line on the first bit line, and extending in a second direction intersecting the first direction;
a first channel pattern between the first bit line and the word line, and extending along a first side wall of the word line; and
a first contact pattern on the first channel pattern,
wherein in a cross-sectional view taken along the first channel pattern in the second direction, the first contact pattern includes:
a connecting part on the first channel pattern, and
a protruding part, which is connected to the connecting part, and extends along a side wall of the first channel pattern.

2. The semiconductor memory device of claim 1,
wherein a width of an upper surface of the first contact pattern in the second direction is greater than a width of an upper surface of the first channel pattern in the second direction.

3. The semiconductor memory device of claim 1,
wherein a width of the upper surface of the first contact pattern in the first direction is the same as a width of the upper surface of the first channel pattern in the first direction.

4. The semiconductor memory device of claim 1, further comprising:
a gate insulating film between the first side wall of the word line and the first channel pattern,
wherein the gate insulating film extends along side walls of the first contact pattern.

5. The semiconductor memory device of claim 1, further comprising:
a second bit line spaced apart from the first bit line in the second direction;
a second channel pattern, which is between the second bit line and the word line, spaced apart from the first channel pattern in the second direction, and extends along the first side wall of the word line;
a second contact pattern, which is on the second channel pattern, and is on a part of a side wall of the second channel pattern; and
an insulating pattern disposed between the first contact pattern and the second contact pattern.

6. The semiconductor memory device of claim 5,
wherein the insulating pattern includes:
a first portion which is between the first contact pattern and the second contact pattern, and
a second portion which is disposed below the first portion relative to the substrate providing a base reference plane and disposed between the first channel pattern and the second channel pattern, and
a width of the first portion in the second direction is less than a width of the second portion in the second direction.

7. The semiconductor memory device of claim 5,
wherein the insulating pattern includes:
a liner film below the first contact pattern and the second contact pattern relative to the substrate providing a base reference plane, and extending along side walls of the first channel pattern and the second channel pattern, and
a filling film on the liner film, and does not overlap the first contact pattern and the second contact pattern in a third direction perpendicular to the first direction and the second direction.

8. The semiconductor memory device of claim 7,
wherein the liner film includes silicon nitride, and
wherein the filling film includes silicon oxide.

9. The semiconductor memory device of claim 1,
wherein a lower surface of the protruding part of the first contact pattern is below an upper surface of the word line, relative to an upper surface of the first bit line providing a base reference plane.

10. The semiconductor memory device of claim 1,
wherein a lower surface of the protruding part of the first contact pattern is above a lower surface of the first channel pattern, relative to an upper surface of the first bit line providing a base reference plane.

11. The semiconductor memory device of claim 1,
wherein a lower surface of the connecting part of the first contact pattern is above an upper surface of the word line, relative to an upper surface of the first bit line providing a base reference plane.

12. The semiconductor memory device of claim 1,
wherein a lower surface of the connecting part of the first contact pattern is below an upper surface of the word line, relative to an upper surface of the first bit line providing a base reference plane.

13. The semiconductor memory device of claim 1,
wherein a lower surface of the word line completely overlaps the first channel pattern in a third direction intersecting the first direction and the second direction.

14. The semiconductor memory device of claim 1, further comprising:
a capacitor, which is on the first contact pattern, connected to the first channel pattern.

15. A semiconductor memory device comprising:
a first bit line extending in a first direction on a substrate;
a word line on the first bit line, and extending in a second direction intersecting the first direction;
a first channel pattern between the first bit line and the word line, and extending in a third direction intersecting the first direction and the second direction along a first side wall of the word line;
a first contact pattern on the first channel pattern;
a second bit line, which is spaced apart from the first bit line in the second direction and extends in the first direction;
a second channel pattern between the second bit line and the word line, spaced apart from the first channel pattern in the second direction, and extending in the third direction along the first side wall of the word line;
a second contact pattern on the second channel pattern; and
an insulating pattern between the first channel pattern and the second channel pattern,
wherein the insulating pattern includes:
a first portion between the first contact pattern and the second contact pattern, and
a second portion below the first portion relative to the substrate providing a base reference plane, and between the first channel pattern and the second channel pattern, and
wherein a width of the first portion is less than a width of the second portion.

16. The semiconductor memory device of claim 15,
wherein a side face of the first contact pattern overlaps a side face of the first channel pattern in the second direction.

17. The semiconductor memory device of claim 15,
wherein a lower surface of the first contact pattern is between a lower surface of the first channel pattern and an upper surface of the first channel pattern.

18. The semiconductor memory device of claim 15,
wherein the first contact pattern includes:
a connecting part on an upper surface of the first channel pattern, and
a protruding part, which is on a lower surface of the connecting part and extends along a side wall of the first channel pattern.

19. The semiconductor memory device of claim 15,
wherein an entire lower surface of the word line extending in the second direction overlaps the first channel pattern in the third direction.

20. A semiconductor memory device comprising:
a first bit line extending in a first direction on a substrate;
a word line on the first bit line, and extending in a second direction intersecting the first direction;
a first channel pattern between the first bit line and the word line, and extending along a first side wall of the word line in a third direction intersecting the first direction and the second direction;
a gate insulating film between the first channel pattern and the word line, and extending in the third direction along a side wall of the first channel pattern and the first side wall of the word line;
a first contact pattern on the first channel pattern;
an insulating pattern extending along a side face of the first contact pattern and a side face of the first channel pattern;
a landing pad on the first contact pattern; and
a capacitor on the landing pad and connected to the first channel pattern,
wherein in a cross-sectional view taken along the first channel pattern in the second direction, the first contact pattern includes:
a connecting part on the first channel pattern, and
a protruding part connected to the connecting part and extending along the side wall of the first channel pattern, and
wherein a lower surface of the protruding part is located above a lower surface of the first channel pattern relative to the substrate providing a base reference plane.
